(19) United States
(12) Patent Application Publication
(10) Pub. No.: US 2025/0268065 A1
(43) Pub. Date: Aug. 21, 2025

(54) Display Apparatus

(71) Applicant: LG Display Co., Ltd., Seoul (KR)

(72) Inventors: Hyoyoung Jun, Paju-si (KR); Sunggyu Kim, Paju-si (KR)

(21) Appl. No.: 18/798,569

(22) Filed: Aug. 8, 2024

(30) Foreign Application Priority Data
Feb. 21, 2024 (KR) 10-2024-0025213

(51) Int. Cl. H10K 59/80

(52) U.S. Cl. CPC H10K 59/873

(57) ABSTRACT

A display apparatus may include a display area on a substrate, the display area including a plurality of light emitting elements and a plurality of transistors, a non-display area surrounding the display area, a first area of the display area, the first area including a hole, and a second area of the display area that is between the first area and a remainder of the display area that is outside the first area and the second area, the second area including a structure having a plurality of metal patterns on different layers with at least one insulating layer between the plurality of metal patterns. The structure reduces at least one of permeation of external moisture to the display area and propagation of one or more cracks in the at least one insulating layer through the first area.

### CROSS-REFERENCE TO RELATED APPLICATION

This application claims priority from Republic of Korea Patent Application No. 10-2024-0025213, filed on Feb. 21, 2024, which is hereby incorporated by reference in its entirety.

### BACKGROUND

### Field

The present disclosure relates to a display apparatus.

### Description of Related Art

Display apparatus are applied to various electronic devices such as a TV, a mobile phone, a laptop PC, and a tablet. To this end, research for developing display apparatus that are thinner, lighter, and have lower power consumption is being continuously conducted.

Examples of the display apparatus may include a Liquid Crystal Display (LCD) apparatus, a Field Emission Display (FED) apparatus, an Organic Light Emitting Diode (OLED) display apparatus, etc.

### SUMMARY

To arrange a camera, etc. in a display area, a hole should be disposed. However, the hole formed in a display apparatus may cause cracks due to external moisture or oxygen permeating the display area.

One or more embodiments of the present disclosure are directed to providing a display apparatus capable of preventing cracks.

Additional features, advantages, and embodiments will be set forth in the description that follows, and in part will be apparent from the description, or may be learned by practice of the inventive concepts provided herein. Other features, advantages, and embodiments of the present disclosure may be realized and attained by the structure particularly pointed out in the written description, or derivable therefrom, and the claims hereof as well as the appended drawings.

A display apparatus according to one or more embodiments of the present disclosure may include a display area on a substrate, the display area including a plurality of light emitting elements and a plurality of transistors, a non-display area surrounding the display area, a first area of the display area, the first area including a hole, and a second area of the display area that is between the first area and a remainder of the display area that is outside the first area and the second area, the second area including a structure having a plurality of metal patterns on different layers with at least one insulating layer between the plurality of metal patterns, wherein the structure reduces at least one of permeation of external moisture to the display area and propagation of one or more cracks in the at least one insulating layer through the first area.

A display apparatus according to one or more embodiments of the present disclosure may include a substrate having a first area including a hole through the substrate, a second area surrounding the first area, and a third area surrounding the first area and the second area, a plurality of insulating layers extending from the second area to the third area, a plurality of transistors on the plurality of insulating layers in the third area, a plurality of light emitting elements in the third area, the plurality of light emitting elements connected to the plurality of transistors and configured to emit light, and a structure in the second area that includes a plurality of metal patterns that are on different layers from each other such that an insulating layer from the plurality of insulating layers is between the plurality of metal patterns, wherein the plurality of metal patterns are in the second area without being in the third area. The plurality of metal patterns may reduce permeation of external moisture to the display area through the plurality of insulating layers or reduce propagation of a crack in the at least one insulating layer toward the display area.

According to one or more embodiments of the present disclosure, since the barrier pattern is between a hole and a display area, it is possible to block or at least reduce external moisture or oxygen from permeating the display area.

According to one or more embodiments of the present disclosure, the crack propagation time may be delayed by increasing the length of the crack propagation path along which the crack propagates toward the display area.

According to one or more embodiments of the present disclosure, since the structure is between the hole and the display area, it is possible to prevent the crack caused by the hole from propagating to the display area or delay the crack propagation spread time.

Therefore, it is possible to prevent dark spot defects in which the pixel does not emit light, reduced luminance, and vertical line defects. Therefore, it is possible to provide the display apparatus that may be driven with low power, thereby reducing a power consumption. Further, it is possible to prevent dark spot defects or vertical line defects, thereby increasing the user's immersion experience in the screen and improving the reliability of the display apparatus.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further embodiments and advantages are discussed below in conjunction with embodiments of the disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure, and incorporated in and constitute a part of this disclosure, illustrate embodiments of the disclosure and together with the description serve to explain principles of the disclosure.

FIG. 1 illustrates a perspective view of a display apparatus according to one or more embodiments of the present disclosure.

FIG. 2 illustrates a cross-sectional view showing one side of the display apparatus of FIG. 1 according to one or more embodiments of the present disclosure.

FIG. 3 illustrates a plan view schematically showing a portion of the display apparatus according to one or more embodiments of the present disclosure.

FIG. 4 illustrates an enlarged plan view of area 4 in which a hole is disposed of FIG. 3 according to one or more embodiments of the present disclosure.

FIG. 5 illustrates a cross-sectional view along line I-I′ in FIG. 4 according to one or more embodiments of the present disclosure.

FIG. 6 illustrates a cross-sectional view of line II-II′ in FIG. 4 according to one or more embodiments of the present disclosure.

FIG. 7 illustrates an enlarged cross-sectional view of area 7 in FIG. 6 according to one or more embodiments of the present disclosure.

FIG. 8 illustrates another modified example of a structure in area 8 in FIG. 6 according to one or more embodiments of the present disclosure.

FIG. 9 illustrates another modified example of a structure in area 9 in FIG. 6 according to one or more embodiments of the present disclosure.

FIG. 10 illustrates another modified example of a structure in area 9 in FIG. 6 according to one or more embodiments of the present disclosure.

FIG. 11 illustrates a cross-sectional view of line II-II′ in FIG. 4 according to one or more embodiments of the present disclosure.

FIG. 12 illustrates an enlarged cross-sectional view of area 12 in FIG. 11 according to one or more embodiments of the present disclosure.

FIG. 13 illustrates another modified example of a structure in area 13 in FIG. 11 according to one or more embodiments of the present disclosure.

FIG. 14 illustrates another modified example of a structure in area 14 in FIG. 11 according to one or more embodiments of the present disclosure.

FIG. 15 illustrates another modified example of a structure in area 15 in FIG. 11 according to one or more embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure embodiments of the present disclosure, the detailed description thereof may have been omitted for brevity. Further, repetitive descriptions can be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more embodiments, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments examples and are provided so that this disclosure may be thorough and complete, and to assist to those of skill in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe example embodiments, and are not intended to limit the scope of the present disclosure. The terms of a singular form may include plural forms unless the context clearly indicates otherwise.

The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

In one or more embodiments, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, where the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more parts may be located between two other parts unless a more limiting term, such as “immediate(ly),” “direct(ly),” or “close(ly),” is used. For example, when a structure is described as being positioned “on,” “on a top of,” “upon,” “on top of,” “over,” “under,” “above,” “below,” “beneath,” “near,” “close to,” “adjacent to,” “beside,” or “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as “after,” “subsequent,” “next,” “before,” “preceding,” “prior to,” or the like a case which is not consecutive or not sequential may be included and thus one or more other events may occur therebetween, unless a more limiting term, such as “just,” “immediate(ly),” or “direct(ly)” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first”, “second,” or the like may be used herein to describe various elements (e.g., layers, films, regions, components, sections, members, parts, regions, areas, portions, steps, operations, and/or the like), these elements should not be limited by these terms. These terms are used only to partition one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, sequence, order, or number of the elements.

For the expression that an element (e.g., layer, film, region, component, section, or the like) is “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element, or that the entirety of the element is provided, disposed, connected, coupled, or the like in, on, with or to another element. The phrase that an element (e.g., layer, film, region, component, section, or the like) “contacts,” “overlaps,” or the like with another element may be understood, for example, as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and may be meant as lines or directions having wider directivities within the range within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any of A, B, and C (e.g., A, B, or C); or some combination of A, B, and C (e.g., A and B; A and C; or B and C); or all of A, B, and C. Furthermore, an expression “A/B” may be understood as A and/or B. For example, an expression “A/B” can refer to only A; only B; A or B; or A and B.

In one or more embodiments, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more embodiments, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more embodiments, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more embodiments, the components of each apparatus according to various embodiments of the present disclosure are operatively coupled and configured.

Unless otherwise defined, all terms including technical and scientific terms used herein have the same meaning as commonly understood by one of ordinary skill in the art to example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

In the following description, various example embodiments of the present disclosure are described in detail with reference to the accompanying drawings. With respect to reference numerals to elements of each of the drawings, the same elements can be illustrated in other drawings, and like reference numerals can refer to like elements unless stated otherwise. The same or similar elements can be denoted by the same reference numerals even though they are depicted in different drawings.

In addition, for convenience of description, a scale, dimension, size, and thickness of each of the elements illustrated in the accompanying drawings can be different from an actual scale, dimension, size, and thickness, and thus, embodiments of the present disclosure are not limited to a scale, dimension, size, and thickness illustrated in the drawings.

Hereinafter, a display apparatus according to one or more embodiments of the present disclosure will be described with reference to the accompanying drawings.

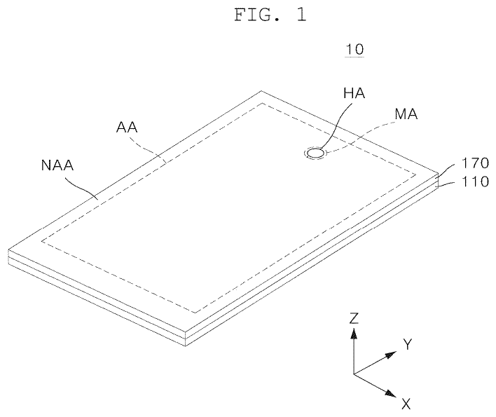

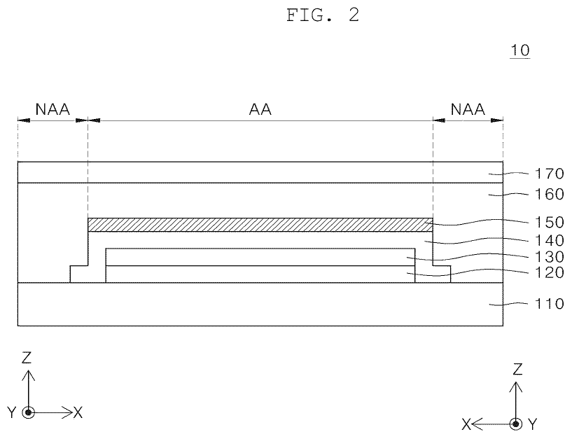

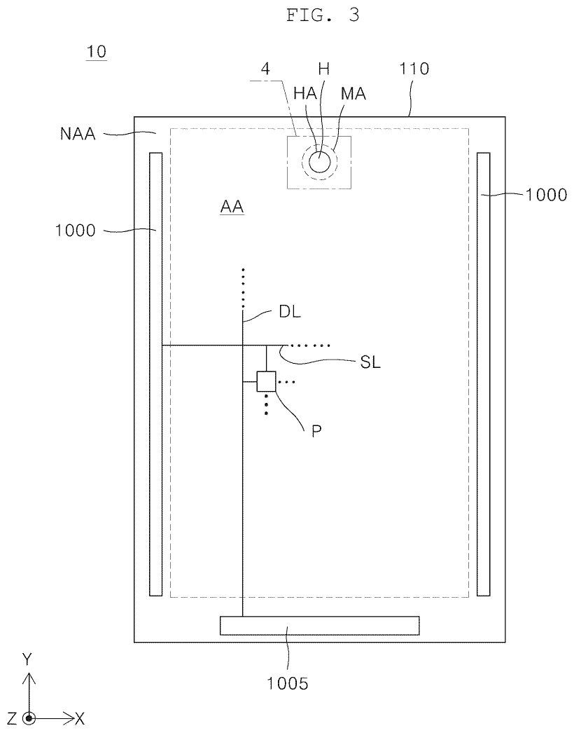

FIG. 1 illustrates a perspective view of a display apparatus according to one or more embodiments of the present disclosure. FIG. 2 illustrates a cross-sectional view showing one side of the display apparatus of FIG. 1 according to one or more embodiments of the present disclosure. FIG. 3 illustrates a plan view schematically showing a portion of the display apparatus according to one or more embodiments of the present disclosure. All components of each display apparatus according to all embodiments of the present disclosure are operatively coupled and configured.

Referring to FIGS. 1 and 3, a display apparatus 10 according to one or more embodiments of the present disclosure may include a first substrate 110 and a second substrate 170 that include a display area (or an active area) AA and a non-display area (or a non-active area) NAA located outside the display area AA.

The first substrate 110 may include transparent plastic or glass, but embodiments of the present disclosure are not limited thereto. The second substrate 170 may include a plastic film of a transparent material, glass substrate, or encapsulation film, but embodiments of the present disclosure are not limited thereto. In a plan view, the first substrate 110 or the second substrate 170 may have a rectangular shape having a long side in a first direction and a short side in a second direction. In another example, the first substrate 110 or the second substrate 170 may have a quadrangular shape having each rounded corner, but embodiments of the present disclosure are not limited thereto. The first direction may be, for example, an X-axis direction or horizontal direction of the first substrate 110, and the second direction may be, for example, a Y-axis direction or vertical direction of the first substrate 110. The second substrate 170 may be disposed on the first substrate 110. The second substrate 170 may cover the first substrate 110. The second substrate 170 may be a cover window, a window cover, or a cover glass, but embodiments of the present disclosure are not limited thereto.

A plurality of pixels may be disposed at the display area AA. A video or an image may be displayed in the display area AA through a plurality of pixels. Several drivers configured to drive the plurality of pixels disposed in the display area AA may be disposed at the non-display area NAA. For example, the driver may include a gate driver, a data driver, a touch driver, and a timing controller, but is not limited thereto.

The display area AA may include a first area HA including a hole. In FIGS. 1 and 3, the first area HA is shown as being disposed at a center portion of the display area AA, but it is not limited thereto.

The first area HA may be an area in which electronic components for adding various functions to the display apparatus 10 are disposed. Examples of the electronic components may include a smartphone, a laptop computer, and a tablet including a camera module configured to take photos or videos or include various sensor devices configured to detect external objects. The sensor device may include at least one or more of a proximity sensor, a gesture sensor, a color sensor, a biometric sensor, and an infrared sensor, but embodiments of the present disclosure are not limited thereto.

The display apparatus may include a second area MA. The second area MA may be part of the display area AA. The second area MA may surround the first area HA and the hole. The second area MA may be an area near the first area HA. The second area MA may be an area surrounding the first area HA and in which no light emitting element is disposed. The first area HA may be a hole area, but embodiments of the present disclosure are not limited thereto. The second area MA may be a hole boundary area, but embodiments of the present disclosure are not limited thereto.

Referring to FIG. 2, the display apparatus 10 may include a structure in which the first substrate 110 and the second substrate 170 are bonded (or attached). A transistor array part 120, a light emitting array part 130, an encapsulation part 140, and a touch part 150 may be disposed between the first substrate 110 and the second substrate 170. The first substrate 110 and the second substrate 170 may be bonded (or attached) through a protective member 160.

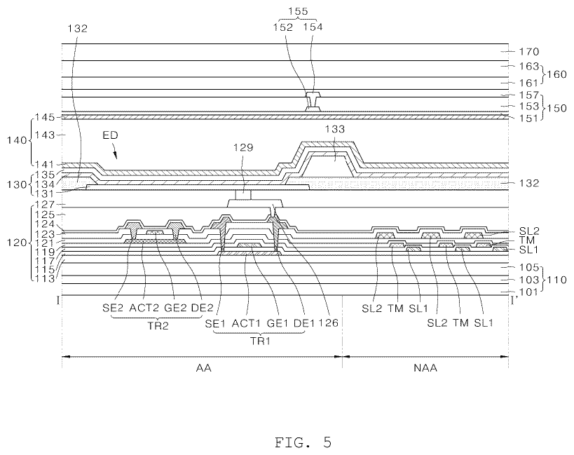

The transistor array part 120 may be disposed on the first substrate 110. The transistor array part 120 may include one or more thin film transistors, one or more scan lines, and one or more data lines. Description of the transistor array part 120 will be provided below with reference to FIG. 5.

The light emitting array part 130 may be disposed on the transistor array part 120. The light emitting element including a first electrode, a light emitting layer, and a second electrode may be disposed in the light emitting array part 130. The light emitting layer may be an organic light emitting layer including an organic material, but embodiments of the present disclosure are not limited thereto. The light emitting layer may emit light by applying a driving current to first and second electrodes disposed above and below the light emitting layer. Description of the light emitting array part 130 will be provided below with reference to FIG. 5. The display apparatus may be an OLED display apparatus, but embodiments of the present disclosure are not limited thereto. For example, the display apparatus may be an inorganic light emitting display apparatus, a quantum dot light emitting display apparatus, a mini-LED display apparatus, or a micro-LED display apparatus, etc.

The encapsulation part 140 may be disposed on the light emitting array part 130. The light emitting layer includes an organic material, and thus may be vulnerable to oxygen and moisture. Therefore, the encapsulation part 140 may prevent the permeation of oxygen or moisture by sealing the light emitting layer including the organic material. The encapsulation part 140 may include an inorganic insulating layer or an organic insulating layer having a multi-layer structure, but embodiments of the present disclosure are not limited thereto. Description of the encapsulation part 140 will be provided below with reference to FIG. 5.

The touch part 150 may be disposed on the encapsulation part 140. The touch part 150 may include one or more touch electrodes configured to detect a user's touch, bridge electrodes configured to electrically connect adjacent touch electrodes, and a protective layer disposed on the touch electrodes, but embodiments of the present disclosure are not limited thereto. Description of the touch part 150 will be provided below with reference to FIG. 5. A protective member 160 may be disposed on the touch part 150. The protective member 160 may cover the touch part 150. The protective member 160 may be disposed between the first substrate 110 and the second substrate 170. The protective member 160 may further include an adhesive member for enhancing an adhesion force between the first substrate 110 and the second substrate 170.

Referring to FIGS. 2 and 3, one or more data lines DL and one or more scan lines SL may be disposed at the display area AA of the first substrate 110. One or more data lines DL and one or more scan lines SL may be disposed on the transistor array part 120. Each of the one or more data lines DL may be disposed to intersect each of the one or more scan lines SL. A pixel P may be formed by the data line DL and/or the scan line SL, and a plurality of pixels P may be disposed at the display area AA. For example, the pixel P may be electrically connected to the scan line SL and the data line DL.

One scan line SL may extend in the first direction of the first substrate 110. Each of the plurality of scan lines SL may be disposed to be spaced apart from each other in the second direction intersecting the first direction. One data line DL may extend in the second direction. Each of the plurality of data lines DL may be disposed to be spaced apart from each other in the first direction intersecting the second direction. The first direction may be the X-axis direction or horizontal direction of the first substrate 110, and the second direction may be the Y-axis direction or vertical direction of the first substrate 110.

The plurality of pixels P may be disposed in a matrix arrangement (M*N, where M and N are natural numbers) on the display area AA of the first substrate 110, but embodiments of the present disclosure are not limited thereto. A light emitting element may be disposed at each pixel P to emit red, green, or blue light, but the embodiments of the present specification are not limited thereto. Further, the pixel may further include a sub-pixel that emits white light.

The non-display area NAA may be disposed near the display area AA. A driver 1000 may be disposed at the non-display area NAA surrounding the display area AA. The driver 1000 may be disposed on the non-display area NAA at one or more sides of the first substrate 110, but embodiments of the present disclosure are not limited thereto. The driver 1000 may include a gate driver, a data driver, or a timing controller, but embodiments of the present disclosure are not limited thereto. Further, the driver 1000 may include power lines through which power voltages are supplied. For example, the gate driver may provide a scan signal to the selected pixels P through the scan line SL, and the data driver may supply a data voltage to the selected pixels P through the data line DL.

A pad part 1005 may be disposed on the non-display area NAA of the first substrate 110 and may include a plurality of electrode pads. The pad part 1005 may be attached to a flexible circuit board and electrically connected to the printed circuit board. The printed circuit board may include an integrated circuit chip and provide power and various signals configured to drive the light emitting element to the display area AA. For example, various signals may include a high potential voltage, a low potential voltage, a scan signal, a data signal, or a touch drive signal, but embodiments of the present disclosure are not limited thereto.

A hole H may be formed by cutting the first substrate 110 by a laser trimming method. Therefore, external moisture or oxygen may permeate toward the display area AA through the cross section exposed by the hole H formed by the laser trimming method. Further, when an external force is applied to the display apparatus 10, cracks may occur in an area in which the hole H is disposed. Once cracks occur, the cracks may propagate toward the display area AA, thereby causing defects such as dark spots at which the pixel does not emit light. Therefore, a structure capable of preventing the cracks will be described below.

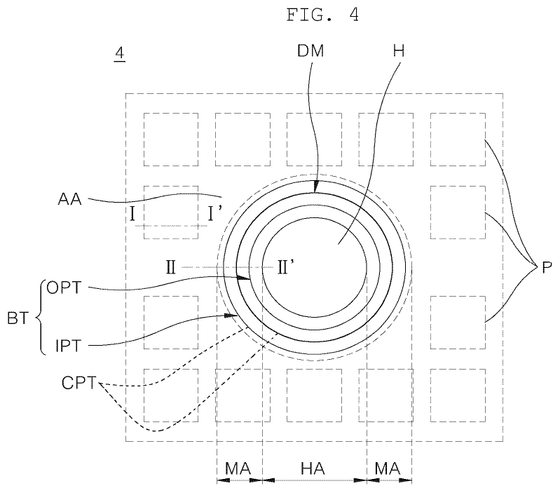

FIG. 4 illustrates an enlarged plan view of area 4 in which a hole is disposed of FIG. 3 according to one or more embodiments of the present disclosure.

Referring to FIGS. 3 and 4, the display area AA of the first substrate 110 may include the first area HA in which the hole H is disposed. The first area HA disposed in the display area AA may be an area in which the hole H permeating from an upper surface to a lower surface of the first substrate 110 is disposed. The first area HA may be the non-display area because no image is displayed.

The hole H may pass through the first substrate 110 in a thickness direction. The hole H may have a closed curve shape in a plan view, but embodiments of the present disclosure are not limited thereto. In one example, the hole H may have a circular shape, but is not limited thereto.

According to one or more embodiments of the present disclosure, the second area MA may be included between the first area HA and the display area AA. The second area MA may surround the first area HA. The pixel P is not disposed at the second area MA, and thus the second area MA may be the non-display area. A barrier pattern BT may be disposed at the second area MA. By configuring the barrier pattern BT in the second area MA, it is possible to prevent the light emitting element in the display area AA from being damaged by moisture or oxygen. Further, by blocking or at least reducing permeation of external moisture or oxygen to the first area HA, it is possible to prevent or at least reduce the occurrence of defects such as dark spots or a reduction in the luminance of the light emitting element.

A dam DM may be disposed at the second area MA.

The dam DM may be disposed between the hole H and light emitting elements in the display area AA. The dam DM may have a closed curve shape surrounding the hole H, but embodiments of the present disclosure are not limited thereto. The dam DM may have the same shape as the hole H, but embodiments of the present disclosure are not limited thereto. In one example, since the dam DM is formed to surround the hole H outside the hole H, the dam DM may have a greater diameter than that of the hole H. Therefore, the dam DM and the hole H may be disposed to be spaced apart from each other. Since the dam DM is formed with a pattern, the dam DAM may be a dam pattern, but embodiments of the present disclosure are not limited thereto.

The barrier pattern BT may include a first barrier pattern OPT and a second barrier pattern IPT. The first barrier pattern OPT may be disposed at a first portion between the hole H and the dam DM in the second area MA. The second barrier pattern IPT may be disposed at a second portion between the dam DM and a boundary of the display area AA in the second area MA. The barrier pattern BT may be a pattern, but embodiments of the present disclosure are not limited thereto.

The first barrier pattern OPT may have a closed curve shape surrounding the hole H, but embodiments of the present disclosure are not limited thereto. The first barrier pattern OPT may have the same shape as the hole H, but embodiments of the present disclosure are not limited thereto. In one example, since the first barrier pattern OPT is formed to surround the hole H outside the hole H, the first barrier pattern OPT may have a greater diameter than that of the hole H. Thus, the first barrier pattern OPT may be disposed at a position spaced apart from the hole H by a predetermined distance. In one example, the first barrier pattern OPT may include one or more patterns, but embodiments of the present disclosure are not limited thereto.

The second barrier pattern IPT may have a closed curve shape surrounding the hole H. The second barrier pattern IPT may have the same shape as the hole H. In one example, the second barrier pattern IPT may be formed to surround the hole H from the outside the hole H, and thus, may have a greater diameter than that of the hole H. Further, since the second barrier pattern IPT is formed to surround the dam DM from outside the dam DM, the second barrier pattern IPT may have a size greater than that of the diameter of the dam DM. Thus, the second barrier pattern IPT may be disposed at a position spaced apart from the hole H by a predetermined distance. In one example, the second barrier pattern IPT may include one or more patterns, but embodiments of the present disclosure are not limited thereto.

With respect to the hole H, the first barrier pattern OPT, the dam DM, and the second barrier pattern IPT may be disposed outward from the hole H. With respect to the hole H, the first barrier pattern OPT, the dam DM, and the second barrier pattern IPT may be disposed outside the hole H. Thus, the diameter of the first barrier pattern OPT disposed closest to (or closest to) the hole H may be the smallest, and the diameter of the second barrier pattern OPT disposed at the furthest distance from the hole H may be the largest.

The light emitting layer that is a component of the light emitting element may be separated or disconnected in the second area MA by configuring the dam DM, the first barrier pattern OPT, and the second barrier pattern IPT in the second area MA between the hole H and the display area AA. By separating or disconnecting the light emitting layer at the second area MA, it is possible to prevent or delay diffusion of moisture or oxygen that may permeate the hole H into the display area AA.

According to one or more embodiments of the present disclosure, structures may be further disposed at the second area MA. A structure CPT may be disposed to overlap at least one structure of the first barrier pattern OPT or the dam DM. For example, the structure CPT may vertically (or in up-and-down direction) overlap at least one of the first barrier pattern OPT or the dam DM. The structure CPT may prevent external moisture or oxygen from permeating the display area AA or prevent cracks from propagating through the first area HA. The structure CPT may prevent cracks occurring in the hole H from propagating to the display area AA or delay the propagation time of the cracks. Therefore, it is possible to prevent dark spot defects or vertical line defects from occurring on the display area AA. The structure CPT may be an anti-crack structure or a crack stopper structure, but embodiments of the present disclosure are not limited thereto.

The structure CPT may have a closed curve shape surrounding the hole H, but embodiments of the present disclosure are not limited thereto. The structure CPT may have the same shape as the hole H. In one example, since the structure CPT is disposed under the dam DM, the structure CPT may have a smaller width than the dam DM, but embodiments of the present disclosure are not limited thereto.

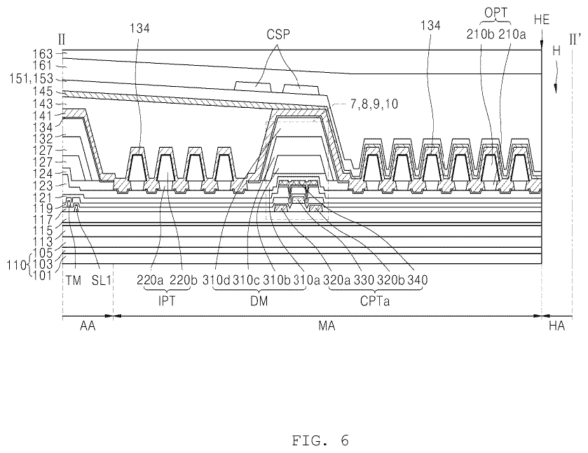

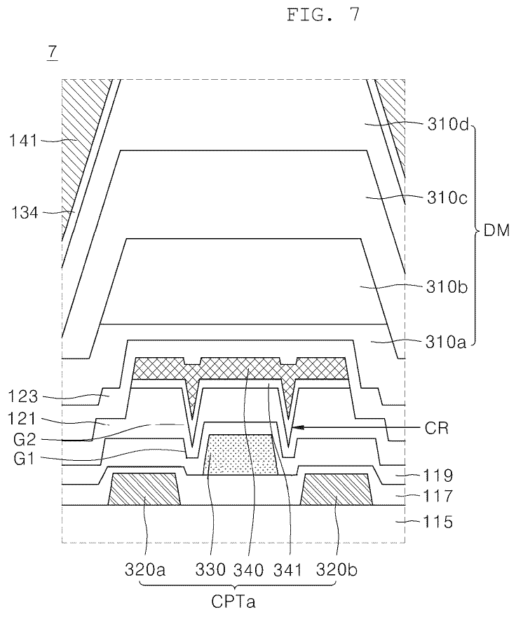

FIG. 5 illustrates a cross-sectional view along line I-I′ in FIG. 4 according to one or more embodiments of the present disclosure. FIG. 6 illustrates a cross-sectional view of line II-II′ in FIG. 4 according to one or more embodiments of the present disclosure. FIG. 7 illustrates an enlarged cross-sectional view of area 7 in FIG. 6 according to one or more embodiments of the present disclosure. For convenience of description, the second substrate 170 is omitted in FIG. 6.

Referring to FIGS. 5 to 7, the first substrate 110 may include a barrier layer 103, and a first base layer 101 and a second base layer 105 that are disposed on both surfaces of the barrier layer 103, respectively. The first base layer 101 and the second base layer 105 may include a flexible insulating material, but embodiments of the present disclosure are not limited thereto. For example, the first base layer 101 and the second base layer 105 may include polyimide, but embodiments of the present disclosure are not limited thereto. The barrier layer 103 may be disposed between the first and second base layers 101 and 105. The barrier layer 103 may support the first and second base layers 101 and 105 having a flexibility (or softness or ductile). The barrier layer 103 may include an insulating material, but embodiments of the present disclosure are not limited thereto. Since the first substrate 110 is formed as multiple layers of the first base layer 101, the barrier layer 103, and the second base layer 105, it is possible to prevent moisture permeation from a back surface (or a rear surface) of the first substrate 110.

A first transistor TR1 may be disposed on the first substrate 110. The first transistor TR1 may include a first semiconductor layer ACT1, a first gate electrode GE1, a first source electrode SE1, and a first drain electrode DE1.

A buffer layer 113 may be disposed between the first substrate 110 and the first transistor TR1. The buffer layer 113 may be disposed on the first substrate 110. The buffer layer 113 may cover a surface of the first substrate 110. For example, the buffer layer 113 may entirely cover a surface of the first substrate 110. The buffer layer 113 may reduce or prevent the permeation of moisture, oxygen, or impurities through the first substrate 110. Therefore, it is possible to protect the first transistor TR1 from moisture, oxygen, or impurities permeating through the first substrate 110. The buffer layer 113 may include multiple layers, but embodiments of the present disclosure are not limited thereto. The buffer layer 113 may include an inorganic insulating film including silicon oxide (SiOₓ) or silicon nitride (SiNₓ), but embodiments of the present disclosure are not limited thereto. For example, the buffer layer 113 may be formed of multiple layers formed by alternately arranging one or more inorganic insulating films, but is not limited thereto.

The first transistor TR1 may be formed of one of an oxide semiconductor layer, a polysilicon semiconductor layer, and a low-temperature polysilicon semiconductor layer, or a combination thereof. For example, the first semiconductor layer ACT1 may include a silicon-based semiconductor material. The first semiconductor layer ACT1 may include a polysilicon semiconductor material or a low-temperature polysilicon semiconductor material, but embodiments of the present disclosure are not limited thereto. For another example, the first semiconductor layer ACT1 may include an oxide semiconductor material. The first semiconductor layer ACT1 may include a channel area, a source area, and a drain area. An area of the first semiconductor layer ACT1 that overlaps the first gate electrode GE1 may be the channel area. For example, an area of the first semiconductor layer ACT1 that vertically (or up-and-down direction) overlaps the first gate electrode GE1 may be the channel area. The source area and the drain area may be disposed at both sides of the channel area.

The first insulating layer 115 may be disposed between the first semiconductor layer ACT1 and the first gate electrode GE1. The first semiconductor layer ACT1 may be covered with the first insulating layer 115. The first insulating layer 115 may be formed of a single layer or multiple layers of silicon oxide (SiOₓ) or silicon nitride (SiNₓ), but is not limited thereto. The first insulating layer 115 may be a gate insulating layer, but embodiments of the present disclosure are not limited thereto.

A light blocking layer may be further included between the buffer layer 113 and the first semiconductor layer ACT1 or between the first substrate 110 and the buffer layer 113. The light blocking layer may block external light incident on the first semiconductor layer ACT1.

The first gate electrode GE1 may be disposed on the first insulating layer 115. The first gate electrode GE1 may be formed of a single layer or multiple layers formed of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited to such a material.

A first pattern SL1 may be disposed on the first insulating layer 115. A plurality of first patterns SL1 may be configured, but embodiments of the present disclosure are not limited thereto. For example, the plurality of first patterns SL1 may be disposed at different positions from the position at which the first gate electrode GE1 is formed on the first insulating layer 115. The plurality of first patterns SL1 may include the same material as the first gate electrode GE1, but embodiments of the present disclosure are not limited thereto. For example, the plurality of first patterns SL1 may be disposed at a line area in which the gate driver is disposed on the non-display area NAA. Each of the plurality of first patterns SL1 may be disposed to be spaced apart from each other.

The second insulating layer 117 may be disposed on the first gate electrode GEL and the plurality of first patterns SL1. The second insulating layer 117 may cover the first gate electrode GE1 and the plurality of first patterns SL1. The second insulating layer 117 may include an inorganic insulating material, but embodiments of the present disclosure are not limited thereto. The second insulating layer 117 may be an interlayer insulating layer, but embodiments of the present disclosure are not limited thereto.

A metal pattern TM may be disposed on the second insulating layer 117. The metal pattern TM may be disposed at a different position from the area in which the first transistor TR1 is disposed. For example, the metal pattern TM may be disposed in the line area in which the gate driver is disposed on the non-display area NAA. The metal pattern TM may be disposed not to overlap the plurality of first patterns SL1. For example, the metal pattern TM may be disposed not to vertically (or in up-and-down direction) overlap the plurality of first patterns SL1. For example, the metal pattern TM may be disposed on another layer between two first patterns SL1 disposed adjacent to each other.

A protective layer 119 may be disposed on the second insulating layer 117. The protective layer 119 may be disposed to cover the metal pattern TM. The protective layer 110 may be a passivation layer, but embodiments of the present disclosure are not limited thereto.

A second transistor TR2 may be disposed on the protective layer 119. The second transistor TR2 may include a second semiconductor layer ACT2, a second gate electrode GE2, a second source electrode SE2, and a second drain electrode DE2.

The second transistor TR2 may be formed of one of an oxide semiconductor layer, a polysilicon semiconductor layer, and a low-temperature polysilicon semiconductor layer, or a combination thereof. For example, the second semiconductor layer ACT2 may include an inorganic insulating material, but embodiments of the present disclosure are not limited thereto. The second semiconductor layer ACT2 may include an oxide semiconductor material such as indium gallium-zinc-oxide (IGZO) or indium-zinc-oxide (IZO), but embodiments of the present disclosure are not limited thereto. For another example, the second semiconductor layer ACT2 may include a polysilicon semiconductor material or a low-temperature polysilicon semiconductor material. The second semiconductor layer ACT2 may include a channel area, a source area, and a drain area. An area of the second semiconductor layer ACT2 that vertically (or in up-and-down direction) overlaps the second gate electrode GE2 may be the channel area. The source area and the drain area may be disposed at both sides of the channel area. The second semiconductor layer ACT2 may be formed of low-temperature polysilicon or polysilicon, but embodiments of the present disclosure are not limited thereto.

A third insulating layer 121 may be disposed between the second semiconductor layer ACT2 and the second gate electrode GE2. The third insulating layer 121 may be formed of a single layer or multiple layers of silicon oxide (SiOₓ) or silicon nitride (SiNₓ), but is not limited thereto. The third insulating layer 121 may be a gate insulating layer, but embodiments of the present disclosure are not limited thereto.

The second gate electrode GE2 may be disposed on the third insulating layer 121. The second gate electrode GE2 may be formed of a single layer or multiple layers formed of one of molybdenum (Mo), aluminum (Al), chromium (Cr), gold (Au), titanium (Ti), nickel (Ni), neodymium (Nd), and copper (Cu), or an alloy thereof.

A second pattern SL2 may be disposed on the third insulating layer 121. A plurality of second patterns SL2 may be configured, but embodiments of the present disclosure are not limited thereto. For example, the plurality of second patterns SL2 may be disposed at different positions from the position at which the second gate electrode GE2 is formed on the third insulating layer 121. The plurality of second patterns SL2 may include the same material as the second gate electrode GE2 of the second transistor TR2, but embodiments of the present disclosure are not limited thereto. For example, the plurality of second patterns SL2 may be disposed at the line area in which the gate driver is disposed on the non-display area NAA. Each of the plurality of second patterns SL2 may be disposed to be spaced apart from each other.

A fourth insulating layer 123 may be disposed on the second gate electrode GE2 and the plurality of second patterns SL2. The fourth insulating layer 123 may cover the second gate electrode GE2 and the plurality of second patterns SL2. The fourth insulating layer 123 may include an inorganic insulating material, but embodiments of the present disclosure are not limited thereto. For example, the fourth insulating layer 123 may include an inorganic insulating film including silicon oxide (SiOₓ) or silicon nitride (SiNₓ), but embodiments of the present disclosure are not limited thereto. The fourth insulating layer 123 may be a gate insulating layer, but embodiments of the present disclosure are not limited thereto.

The second source electrode SE2 and the second drain electrode DE2 may be disposed on the fourth insulating layer 123. The second source electrode SE2 and the second drain electrode DE2 may be electrically connected to the source area and drain area of the second semiconductor layer ACT2, respectively, through holes passing through the fourth insulating layer 123 and the third insulating layer 121.

A fifth insulating layer 124 may be disposed on the fourth insulating layer 123. The fifth insulating layer 124 may include an inorganic insulating material, but embodiments of the present disclosure are not limited thereto. For example, the fifth insulating layer 124 may include an inorganic insulating film including silicon oxide (SiOₓ) or silicon nitride (SiNₓ), but embodiments of the present disclosure are not limited thereto. The fifth insulating layer 124 may be an interlayer insulating layer, but embodiments of the present disclosure are not limited thereto.

The first source electrode SE1 and the first drain electrode DE1 may be disposed on the fifth insulating layer 124. The first source electrode SE1 and the first drain electrode DE1 may be disposed at different positions from the second source electrode SE2 and the second drain electrode DE2. The first source electrode SE1 and the first drain electrode DE1 may be electrically connected to the source area and drain area of the first semiconductor layer ACT1, respectively, through holes passing through the fourth insulating layer 123, the third insulating layer 121, the protective layer 119, the second insulating layer 117, and the first insulating layer 115.

Planarization layers 125 and 127 may be disposed on the fifth insulating layer 124. The planarization layers 125 and 127 may include the first planarization layer 125 and the second planarization layer 127, but embodiments of the present disclosure are not limited thereto.

The first planarization layer 125 may include a contact hole exposing a portion of a surface of the first drain electrode DE1 of the first transistor TR1, but is not limited thereto. For example, the portion of the surface of the first source electrode SE1 may be exposed. A first contact electrode 126 may fill the contact hole while one surface is in contact with the first drain electrode DE1. The first contact electrode 126 may partially extend to the surface of the first planarization layer 125 while filling the contact hole.

The first planarization layer 125 may planarize a step caused by lower elements including the first and second transistors TR1 and TR2. The first planarization layer 125 may be formed of an organic insulating material such as an acryl resin, an epoxy resin, a phenolic resin, a polyamide resin, or a polyimide resin. However, embodiments of the present disclosure are not limited thereto and the planarization layer 115 may include an organic insulating material capable of planarizing the step.

The second planarization layer 127 may include a contact hole exposing a portion of a surface of the first contact electrode 126. The contact hole passing through the second planarization layer 127 may be filled with a second contact electrode 129, and one surface of the second contact electrode 129 may be electrically connected in contact with the first contact electrode 126.

The light emitting array part 130 may be disposed on the second planarization layer 127. The light emitting array part 130 may include a bank 132, a plurality of light emitting elements ED, and a spacer 133, but embodiments of the present disclosure are not limited thereto. Each of the plurality of light emitting elements ED may include a first electrode 131, a light emitting layer 134, and a second electrode 135. The first electrode 131 may be an anode electrode or a pixel electrode, and the second electrode 135 may be a cathode electrode or an opposing electrode, but embodiments of the present disclosure are not limited thereto.

The first electrode 131 may be disposed on the second planarization layer 127. One surface of the first electrode 131 may be in contact with an upper surface of the second contact electrode 129. Thus, the first electrode 131 may be electrically connected to the drain electrode DE1 of the first transistor TR1 through the second contact electrode 129 and the first contact electrode 126.

The first electrode 131 may include a metal oxide such as indium tin oxide (ITO) or indium zinc oxide (IZO), but embodiments of the present disclosure are not limited thereto. In another example, the first electrode 131 may include a single-layer or multilayered structure including a reflective metal film formed of silver (Ag), aluminum (Al), gold (Au), nickel (Ni), and chromium (Cr) or an alloy thereof, but is not limited thereto.

The bank 132 may be disposed on the second planarization layer 127. The bank 132 may define each pixel P (see FIG. 3). Thus, the bank 132 may be formed to cover an edge (a periphery) of the first electrode 131. Further, the bank 132 may prevent light of different colors from being mixed and output between adjacent pixels. The bank 132 may include an organic insulating film such as polyimide or an epoxy, but is not limited thereto. For example, the bank 132 may be formed of a material including black pigment, or an organic material such as a benzocyclobutene resin, a polyimide resin, an acrylic resin, or a photosensitive polymer, but embodiments of the present disclosure are not limited thereto. When the bank 132 is formed of a material including black pigment or black dye, the bank 132 may be a black bank. When the bank 132 is formed of a material including black pigment or black dye, it is possible to block light from the outside or light reflected from the outside, thereby further increasing the luminance of the display apparatus.

The spacer 133 may be disposed on the bank 132. The spacer 133 may be formed of the same material as the bank 132, but embodiments of the present disclosure are not limited thereto. The spacer 133 may prevent the light emitting layer 134 from being directly impacted by an external impact, thereby protecting the light emitting layer 134.

The light emitting layer 134 may be disposed on the first electrode 131. In one example, the light emitting layer 134 may include an organic material that emits different colors in each pixel, but embodiments of the present disclosure are not limited thereto. For example, the light emitting layer 134 may emit light of one color among red, green, blue, and white, but is not limited thereto. In another example, the light emitting layer 134 may be formed of an organic material that emits white light and may display one of red, green, or blue by a color filter.

The light emitting layer 134 may include a stack structure including a hole transporting layer HTL, an emission material layer EML, an electron transporting layer ETL, a hole blocking layer HBL, a hole injecting layer HIL, an electron blocking layer EBL, and an electron injecting layer EIL, but embodiments of the present disclosure are not limited thereto. When the light emitting layer 134 includes the stack structure, the light emitting layer 134 may include one or more stack structures, but embodiments of the present disclosure are not limited thereto. For example, a charge generation layer may be further included between one or more stack structures. The charge generation layer may include a P-type charge generation layer and an N-type charge generation layer. The emission material layer EML of the light emitting layer 134 may emit light through recombination of holes injected from the first electrode 131 and electrons injected from the second electrode 135.

The emission material layer EML may be formed over an entire surface of the display area AA to cover exposed surfaces of the first electrode 131 and the bank 132. As shown in FIG. 6, the light emitting layer 134 may be formed to extend from the display area AA to the second area MA.

The second electrode 135 may be disposed on the light emitting layer 134. The second electrode 135 may be formed to cover the light emitting layer 134. The second electrode 135 may be commonly formed on the plurality of pixels P. The second electrode 135 may include a metal oxide such as indium tin oxide (ITO) or indium zinc oxide (IZO), but embodiments of the present disclosure are not limited thereto. In another example, the second electrode 135 may include a single-layer or multilayered structure including a reflective metal film formed of silver (Ag), aluminum (Al), gold (Au), nickel (Ni), and chromium (Cr), or an alloy thereof, but is not limited thereto.

The light emitting element ED including the first electrode 131, the light emitting layer 133, and the second electrode 135 may be formed. The encapsulation part 140 may be disposed on the light emitting element ED. The encapsulation part 140 may protect the light emitting element ED from external oxygen or moisture. The encapsulation part 140 may cover the display area AA and extend to the non-display area NAA surrounding the display area AA.

The encapsulation part 140 may include a multilayered structure in which a first encapsulation layer 141, a second encapsulation layer 143, and a third encapsulation layer 145 are disposed, but embodiments of the present disclosure are not limited thereto. The encapsulation part 140 may have configuration in which the second encapsulation layer 143 is disposed between the first encapsulation layer 141 and the third encapsulation layer 145, but embodiments of the present disclosure are not limited thereto. In one example, the first encapsulation layer 141, the second encapsulation layer 143, and the third encapsulation layer 145 may extend to a hole end HE of the second area MA as shown in FIG. 6.

The first encapsulation layer 141 may be disposed on the second electrode 135. The first encapsulation layer 141 may include an inorganic insulating material. For example, the first encapsulation layer 141 may include at least one or more inorganic insulating materials among silicon nitride (SiNₓ), silicon oxide (SiOₓ), and silicon oxynitride (SiON), but embodiments of the present disclosure are not limited thereto.

The second encapsulation layer 143 may be disposed on the first encapsulation layer 141. For example, the second encapsulation layer 143 may cover the first encapsulation layer 141 and have a sufficient thickness to have a flat surface. The second encapsulation layer 143 may prevent foreign substances from permeating the light emitting element ED. The second encapsulation layer 143 may include an organic insulating material, but embodiments of the present disclosure are not limited thereto. For example, the second encapsulation layer 143 may include at least one or more materials of an epoxy, polyimide, polyethylene, and acrylate, but embodiments of the present disclosure are not limited thereto.

The third encapsulation layer 145 may be disposed on the second encapsulation layer 143. The third encapsulation layer 145 may include an organic insulating material, but embodiments of the present disclosure are not limited thereto. For example, the third encapsulation layer 145 may include at least one or more inorganic insulating materials among silicon nitride (SiNₓ), silicon oxide (SiOₓ), and silicon oxynitride (SiON), but embodiments of the present disclosure are not limited thereto.

The touch part 150 may be disposed on the encapsulation part 140. The touch part 150 may include a buffer layer 151, an insulating layer 153, a plurality of touch electrodes 155, and an interlayer insulating layer 157, but embodiments of the present disclosure are not limited thereto. The plurality of touch electrodes 155 may include a plurality of conductive patterns 154 and a plurality of bridge electrodes 152. The plurality of conductive patterns 154 and the plurality of bridge electrodes 152 may be disposed on different layers. For example, the plurality of bridge electrodes 152 may be disposed on the buffer layer 151. The plurality of conductive patterns 154 may be disposed on the insulating layer 153.

The insulating layer 153 may be disposed between the conductive pattern 154 and the bridge electrode 152. The plurality of conductive patterns 154 may be disposed to be spaced apart from each other on the insulating layer 153. The bridge electrode 152 may electrically connect adjacent conductive patterns 154. To this end, the conductive pattern 154 may pass through the insulating layer 153 and may be electrically connected to the bridge electrode 154. Adjacent conductive patterns 154 may be insulated from each other by the interlayer insulating layer 157.

One or more crack sensing patterns (or crack detecting patterns) CSP may be disposed on the insulating layer 153. For example, one or more crack sensing patterns CSP may be disposed at different positions from a position at which the conductive pattern 154 is formed on the insulating layer 153. For example, referring to FIG. 6, one or more crack sensing patterns CSP may be disposed on the second area MA. At least one of the one or more crack sensing patterns CSP may be disposed to overlap the dam DM. For example, the at least one of the one or more crack sensing patterns CSP may be disposed to vertically (or in up-and-down direction) overlap the dam DM. The crack sensing pattern CSP may detect defects such as cracks that may occur in the process of forming the hole H.

The conductive pattern 154, the bridge electrode 152, and the crack sensing pattern CSP may include a single layer or a multi-layer including any one of molybdenum (Mo), aluminum (Al), chromium (Cr), gold (Au), titanium (Ti), nickel (Ni), neodymium (Nd), and copper (Cu), or an alloy thereof, but embodiments of the present disclosure are not limited thereto.

A protective member 160 may be disposed on the touch part 150. The protective member 160 may cover a step caused by the touch part 150 and have a sufficient thickness to have a flat surface. The protective member 160 may prevent foreign substances, moisture, or oxygen from permeating the touch part 150. The protective member 160 may be formed of a multilayered structure formed by alternately arranging organic insulating layers and inorganic insulating layers, but embodiments of the present disclosure are not limited thereto.

For example, the protective member 160 may include a first protective layer 161 and a second protective layer 163. The first protective layer 161 and the second protective layer 163 may include an organic insulating layer, but embodiments of the present disclosure are not limited thereto.

The second substrate 170 may be disposed on the protective member 160. The second substrate 170 may cover the first substrate 110. The second substrate 170 may serve as a cover window or a cover substrate. The second substrate 170 may include a plastic film or a glass substrate, but embodiments of the present disclosure are not limited thereto. An adhesive member may be further included between the protective member 160 and the second substrate 170. The adhesive member may increase an adhesion force between the first substrate 110 and the second substrate 170. The adhesive member may include a pressure-sensitive adhesive (PSA), an optically cleared resin (OCR), or an optically cleared adhesive (OCA), but embodiments of the present disclosure are not limited thereto.

Referring to FIGS. 4 and 6, the display apparatus according to one or more embodiments of the present disclosure may have the dam DM, the pattern BT, and a first structure CPTa disposed at the second area MA. The dam DM may prevent overflowing of the second encapsulation layer 253 including an organic insulating material toward the hole H.

The dam DM may include a first layer 310a, a second layer 310b, a third layer 310c, and a fourth layer 310d, but embodiments of the present disclosure are not limited thereto. For example, the dam DM may include a structure in which the first layer 310a, the second layer 310b, the third layer 310c, and the fourth layer 310d are disposed or stacked from bottom to top, but is not limited thereto. The first layer 310a may be formed in the process of forming the fifth insulating layer 124, but embodiments of the present disclosure are not limited thereto. The second layer 310b may be formed in the process of forming the second planarization layer 127, but embodiments of the present disclosure are not limited thereto. The third layer 310c may be formed in the process of forming the bank 132, but embodiments of the present disclosure are not limited thereto. The fourth layer 310d may be formed in the process of forming the spacer 133, but embodiments of the present disclosure are not limited thereto. For example, the first layer 310a of the dam DM may include the same material as the fifth insulating layer 124, but embodiments of the present disclosure are not limited thereto. The second layer 310b may include the same material as the second planarization layer 127, but embodiments of the present disclosure are not limited thereto. The third layer 310c may include the same material as the bank 132, but embodiments of the present disclosure are not limited thereto. The fourth layer 310d may include the same material as the spacer 133, but embodiments of the present disclosure are not limited thereto.

Since the second layer 310b of the dam DM has a smaller size than the first layer 310a, an edge portion (or a periphery portion) of an upper surface of the first layer 310a may be exposed. The third layer 310c of the dam DM may cover the second layer 310b. The third layer 310c of the dam DM may cover an exposed surface of the first layer 310a. Further, since the fourth layer 310d of the dam DM has a larger size than the third layer 310c, the fourth layer 310d may cover the third layer 310c and cover the exposed surface of the first layer 310a not covered by the third layer 310c.

The hole H may be formed to pass through from the second protective layer 163 to the first substrate 110 by a laser trimming method. External moisture or oxygen may permeate toward the display area AA through the exposed cross section of the hole H. For example, moisture may permeate from the hole end HE of the second area MA to the display area AA. Therefore, the barrier pattern BT that prevents external moisture or oxygen from permeating the display area AA or toward the display area AA together with the dam DM may be disposed on the second area MA.

Referring to FIGS. 4 and 6, the barrier pattern BT according to one or more embodiments of the present disclosure may include a first barrier pattern OPT and a second barrier pattern IPT. The first barrier pattern OPT may be disposed at a first area between the hole H and the dam DM in the second area MA. The second barrier pattern IPT may be disposed at a second area of the second area MA between the dam DM and a boundary of the display area AA.

The first barrier pattern OPT may include a lower structure 210a and an upper structure 210b, but embodiments of the present disclosure are not limited thereto. The first barrier pattern OPT may include a structure in which the lower structure 210a and the upper structure 210b are disposed or stacked, but embodiments of the present disclosure are not limited thereto. The first barrier pattern OPT may be an external barrier pattern, but embodiments of the present disclosure are not limited thereto.

The lower structure 210a may be formed of the same material in the same process as the third interlayer insulating layer 124, but is not limited thereto. For example, the lower structure 210a may be formed by a single layer or multiple layers of an inorganic insulating layer such as silicon oxide (SiOₓ) or silicon nitride (SiNₓ), but is not limited thereto.

The upper structure 210b may be formed of the same material in the same process as the second planarization layer 127, but is not limited thereto. For example, the upper structure 210b may include an organic insulating material such as acryl resin, an epoxy resin, a phenol resin, a polyamide resin, or a polyimide resin, but is not limited thereto.

The second barrier pattern IPT may be formed in the same process as the first barrier pattern OPT, but embodiments of the present disclosure are not limited thereto. Therefore, a lower structure 220a of the second barrier pattern IPT may be the same as a lower structure 210a of the first barrier pattern OPT, and an upper structure 220b of a second barrier pattern IPT may be the same as an upper structure 210b of the first barrier pattern OPT, but embodiments of the present disclosure are not limited thereto. The second barrier pattern IPT may be an internal barrier pattern, but embodiments of the present disclosure are not limited thereto.

The upper structures 210b and 220b of the first barrier pattern OPT and the second barrier pattern IPT may have a regular taper shape in which a width of the lower surface is greater than a width of the upper surface, but embodiments of the present disclosure are not limited thereto. The lower structures 210a and 220a of the first barrier pattern OPT and the second barrier pattern IPT may have a regular taper shape in which the width of the lower surface is greater than the width of the upper surface, but embodiments of the present disclosure are not limited thereto. Further, the widths of the lower surfaces of the upper structures 210b and 220b of the first barrier pattern OPT and the second barrier pattern IPT may be greater than the widths of the upper surfaces of the lower structures 210a and 220a thereof, but embodiments of the present disclosure are not limited thereto. The lower structures 210a and 220a of the first barrier pattern OPT and the second barrier pattern IPT may have an undercut structure, but embodiments of the present disclosure are not limited thereto. For example, outermost portions of the lower structures 210a and 220a of the first barrier pattern OPT and the second barrier pattern IPT may have an undercut structure that is undercut inward more than outermost portions of the lower surfaces of the upper structures 210b and 220b, but embodiments of the present disclosure are not limited thereto. Therefore, the outermost portions of the lower surfaces of the upper structures 210b and 220b of the first barrier pattern OPT and the second barrier pattern IPT may have a shape that protrudes more than the lower structures 210a and 220a.

When the light emitting layer 134 is formed in a state in which the second barrier pattern IPT and the first barrier pattern OPT are disposed, the light emitting layer 134 may be formed on surfaces of the upper structures 210b and 220b of the first barrier pattern OPT and the second barrier pattern IPT. Further, the light emitting layer 134 may also be formed on a surface of the fourth insulating layer 123 exposed between adjacent second barrier patterns IPT and between adjacent first barrier patterns OPT. Further, the light emitting layer 134 may be formed on an exposed surface of the dam DM.

Since each of the second barrier pattern IPT and the first barrier pattern OPT has the undercut structure, the light emitting layer 134 may not be formed on sidewalls of the lower structures 210a and 220a. Therefore, the continuity of the light emitting layer 134 is broken in the second area MA, and thus the light emitting layer 134 may be disconnected.

The light emitting layer 134 may serve as a permeation path of moisture or oxygen. Therefore, the light emitting layer 134 may be disconnected between adjacent second barrier patterns IPT and between adjacent first barrier patterns OPT, thereby preventing moisture or oxygen permeating from the outside from permeating toward the display area AA or delaying the permeating time.

The first encapsulation layer 141 may be disposed on the light emitting layer 134 in the second area MA. The first encapsulation layer 141 may be disposed on the second barrier pattern IPT and the first barrier pattern OPT. The first encapsulation layer 141 may be disposed to cover the surfaces of the upper structures 210b and 220b and side surfaces of the lower structures 210a and 220a of the first barrier pattern OPT and the second barrier pattern IPT. The first encapsulation layer 141 may be disposed on the dam DM. The first encapsulation layer 141 may cover the surface of the dam DM. The first encapsulation layer 141 may have a shape that fills a space between adjacent second barrier patterns IPT and a space between adjacent first barrier patterns OPT, and fills a space between the second barrier pattern IPT and the dam DM and between a space between the dam DM and the first barrier pattern OPT, but is not limited thereto. For example, since the space between the second barrier patterns IPT and the space between the first barrier patterns OPT may be small, the first encapsulation layer 141 may not fill all of the spaces. In this case, a space may remain on a portion (or some portions) of side surfaces of the lower structure 210a of the first barrier pattern OPT and the lower structure 220a of the second barrier pattern IPT. The space remaining on the portion of the side surface of the lower structure 210a of the first barrier pattern OPT may be covered by the third encapsulation layer 145. Further, the space remaining on the portion of the side surface of the lower structure 220a of the second barrier pattern IPT may be covered (of filled) by the second encapsulation layer 143.

The second encapsulation layer 143 may be disposed on the first encapsulation layer 141. The second encapsulation layer 143 may be formed to extend to the second portion of the second area MA disposed between the display area AA and the dam DM. The second portion may be an area between the dam DM and the boundary of the display area AA in the second area MA. Since the dam DM may block overflowing of the second encapsulation layer 143, the second barrier patterns IPT disposed on the second portion are covered with the second encapsulation layer 143, but the first barrier pattern OPT disposed on the first portion of the second area MA may not be covered with the second encapsulation layer 143. The first portion may be an area between the hole H and the dam DM in the second area MA.

The third encapsulation layer 145 may be disposed on the second encapsulation layer 143. The third encapsulation layer 145 may be formed to extend from the display area AA to the second area MA. Therefore, the first portion of the second area MA in which the first barrier patterns OPT are disposed may be formed in a structure in which the first encapsulation layer 141 and the third encapsulation layer 145 are disposed or stacked in contact with each other. In one example, the first encapsulation layer 141 does not fully fill the space between the second barrier patterns IPT and the space between the first barrier patterns OPT, and the spaces may remain on the side surfaces of the lower structures 210a and 220a. In this case, the spaces may be sealed by the structure in which the first encapsulation layer 141 and the third encapsulation layer 145 are disposed in contact with each other or stacked.

The insulating structures 151 and 153 may be disposed on the third encapsulation layer 145. The insulating structures 151 and 153 may be the structures 151 and 153 including the buffer layer 151 and the insulating layer 153. The insulating structures 151 and 153 may include an inorganic insulating material, but embodiments of the present disclosure are not limited thereto. The insulating structures 151 and 153 may be disposed on the first barrier pattern OPT. The insulating structures 151 and 153 may cover the first barrier pattern OPT.

The first protective layer 161 and the second protective layer 163 may be disposed on the insulating structures 151 and 153. The first protective layer 161 and the second protective layer 163 may include an organic insulating layer, but embodiments of the present disclosure are not limited thereto. The first protective layer 161 and the second protective layer 163 may extend from the display area AA to the hole end HE of the second area MA. Thus, the first protective layer 161 and the second protective layer 163 may cover at least one or more of the second barrier pattern IPT and the first barrier pattern OPT. For example, the first protective layer 161 and the second protective layer 163 may cover both the second barrier pattern IPT and the first barrier pattern OPT. Further, cracks may occur at the hole end HE of the hole area HA. The cracks may occur when an external force is applied, such as laser trimming. For example, the cracks occurring at the hole end HE may occur in a layer including an inorganic insulating material. For example, the cracks may occur in the fourth insulating layer 123 or the fifth insulating layer 124. The cracks occurring in the fourth or fifth insulating layers 123 and 124 may propagate toward the display area AA that is a direction in which the inorganic insulating material is disposed.

When the cracks occurring at the hole end HE propagates to the area in which the second barrier pattern IPT is disposed, a dark spot defect in which the pixel in the display area AA adjacent to the second barrier pattern IPT does not emit light may occur. Further, when the cracks further propagate toward the display area AA and propagate to the line area in which the plurality of first patterns SL1, etc. are disposed, a line defect visible to a user as a vertical line may occur. The dark spot defects or line defects may be visible to the user to reduce the immersion experience in the video or image, thereby degrading the reliability of the display apparatus.

Therefore, in one or more embodiments of the present disclosure, the first structure CPTa may be disposed in the second area MA to prevent or delay the propagation of cracks toward the display area AA.

Referring to FIGS. 6 and 7, the first structure CPTa may be disposed to overlap the dam DM. For example, the first structure CPTa may be disposed to vertically (or in up-and-down direction) overlap the dam DM. For example, the first structure CPTa may be disposed under the first layer 310a of the dam DM. The first structure CPTa may include one or more first patterns 320a and 320b, a third pattern 330, and second patterns 340 and 341. For example, the first structure CPTa may be a structure in which the one or more first patterns 320a and 320b, the third pattern 330, and the second patterns 340 and 341 are disposed. For example, the one or more first patterns 320a and 320b, the third pattern 330, and the second patterns 340 and 341 may be disposed on different layers. Each of the patterns 320a, 320b, 330, 340, 341 can be also referred to as a corresponding “metal layer pattern.”

The one or more first patterns 320a and 320b may be formed in the process of forming the first gate electrode GE1, but embodiments of the present disclosure are not limited thereto. The one or more first patterns 320a and 320b may include the same material as the first gate electrode GE1, but embodiments of the present disclosure are not limited thereto. For example, the one or more of the first patterns 320a and 320b may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but is not limited thereto.

The one or more first patterns 320a and 320b may include the first pattern 320a and the second pattern 320b. The first pattern 320a and the second pattern 320b may be disposed to be spaced apart from each other on the first insulating layer 115. Thus, a space may be present between the first pattern 320a and the second pattern 320b. The first and second patterns 320a and 320b may be covered with the second insulating layer 117. For example, the second insulating layer 117 may be disposed on the first and second patterns 320a and 320b.

The third pattern 330 may be formed in the process of forming the metal pattern TM, but embodiments of the present disclosure are not limited thereto. The third pattern 330 may include the same material as the metal pattern TM, but embodiments of the present disclosure are not limited thereto. The third pattern 330 may be disposed on the second insulating layer 117. The third pattern 330 may be disposed so as not to overlap the first pattern 320a or the second pattern 320a. For example, the third pattern 330 may be disposed in a space between the first pattern 320a and the second pattern 320b spaced apart from each other. The third pattern 330 may be covered with the protective layer 119. The protective layer 119 may be disposed on the third pattern 330. The protective layer 119 may include a first groove G1. For example, the protective layer 119 may include the first groove G1 formed by a step caused by the space between the first patterns 320a and 320b disposed thereunder. The first groove G1 may be disposed at both sides of the third pattern 330. For example, the first groove G1 may have a shape like a letter “W,” but embodiments of the present disclosure are not limited thereto.

The second patterns 340 and 341 may be formed in the process of forming the second gate electrode GE2, but embodiments of the present disclosure are not limited thereto. The second patterns 340 and 341 may include the same material as the second gate electrode GE2, but embodiments of the present disclosure are not limited thereto. For example, the second pattern 340 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but is not limited thereto.

The second patterns 340 and 341 may be disposed on the third insulating layer 121. The third insulating layer 121 may include the first groove G1 and a second groove G2. The third insulating layer 121 may include the second groove G2 overlapping the first groove G1. For example, the third insulating layer 121 may include the second groove G2 vertically (or in up-and-down direction) overlapping the first groove G1. The first groove G1 and the second groove G2 may extend from an upper surface of the third insulating layer 121 towards a lower surface of the third insulating layer 121. The second patterns 340 and 341 may fill the second groove G2. Thus, the second patterns 340 and 341 and the third insulating layer 121 may have an uneven shape (or a concave-convex shape), but embodiments of the present disclosure are not limited thereto. For example, the second patterns 340 and 341 and the third insulating layer 121 may have an uneven shape (or a concave-convex shape) in a cross-sectional view, but embodiments of the present disclosure are not limited thereto. For example, the uneven shape (or the concave-convex shape) may have the shape of the letter “W,” but embodiments of the present disclosure are not limited thereto. A second pattern 340 may be disposed on a second pattern 341 without any of the insulating layers between the second pattern 340 and the second pattern 341. The second patterns 340 and 341 may overlap the first patterns 320a and 320b and the third pattern 330. For example, the second patterns 340 and 341 may vertically (or in up-and-down direction) overlap the first patterns 320a and 320b and the third pattern 330.

The second patterns 340 and 341 may be formed in the same process as the second gate electrode GE2, but embodiments of the present disclosure are not limited thereto. The second patterns 340 and 341 may include the 2-1 pattern 340 and the 2-2 pattern 341. For example, the second patterns 340 and 341 may include a structure in which the 2-1 pattern 340 and the 2-2 pattern 341 are disposed, but are not limited thereto. For example, the second patterns 340 and 341 may include a single-layer pattern, but embodiments of the present disclosure are not limited thereto. The 2-1 pattern 340 may be a gate pattern or a gate metal pattern, but embodiments of the present disclosure are not limited thereto. The 2-2 pattern 341 may be a gate pattern or a gate metal pattern, but embodiments of the present disclosure are not limited thereto.

Since one or more first patterns 320a and 320b and the third pattern 330 are disposed on different layers and are staggered so as not to overlap each other, the first groove G1 and the second groove G2 may be disposed to overlap the dam DAM. For example, the first groove G1 and the second groove G2 may be disposed to vertically (or in up-and-down direction) overlap the dam DM. The first groove G1 and the second groove G2 may prevent a crack CR from propagating toward the display area AA or delay the crack propagation time by increasing the length of the crack propagation path. For example, a propagation path of the crack CR occurring in the fourth insulating layer 123 including an inorganic insulating material may be blocked by the second patterns 340 and 341 including the material filling the second groove G2 as shown by the arrow in FIG. 7. The material filling the second groove G2 may be a metal material, but embodiments of the present disclosure are not limited thereto.

Further, as a length of the propagation path of the crack CR increases along the uneven shape (or a concave-convex shape) of the third insulating layer 121, the propagation time of the crack CR toward the display area AA may be delayed. Therefore, it is possible to prevent the occurrence of dark spot defects or line defects, thereby improving the reliability of the display apparatus.

The first structure CPTa may be changed (or vary) according to the shapes of the first pattern, the third pattern, and/or the second pattern.

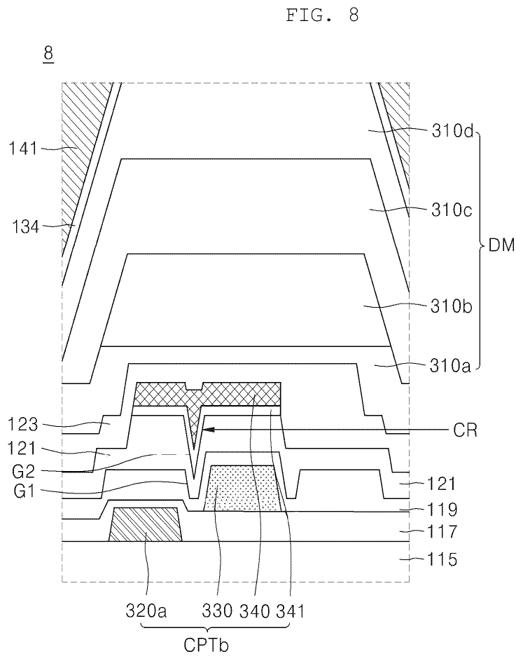

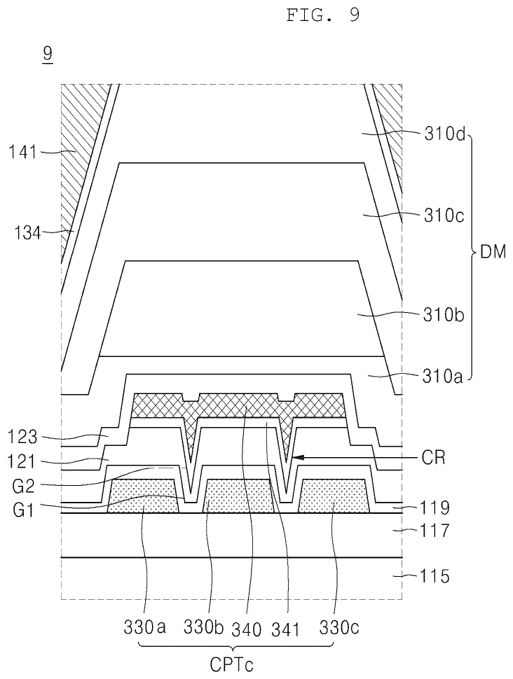

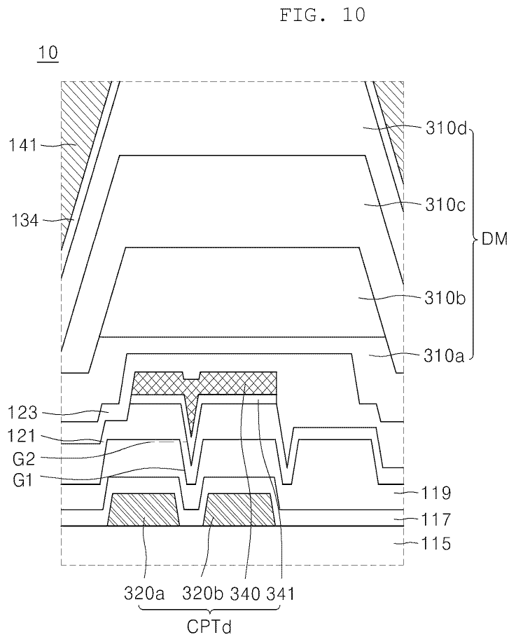

FIG. 8 illustrates another modified example of a structure in area 8 in FIG. 6 according to one or more embodiments of the present disclosure. FIG. 9 illustrates another modified example of a structure in area 9 in FIG. 6 according to one or more embodiments of the present disclosure. FIG. 10 illustrates another modified example of a structure in area 9 in FIG. 6 according to one or more embodiments of the present disclosure. Since FIGS. 8 to 10 are substantially the same as FIG. 7 except for the shape of the structure, the same reference numerals are denoted, and duplicate descriptions thereof may be omitted or briefly described.

Referring to FIG. 8, a second structure CPTb may be disposed to overlap the dam DM. For example, the second structure CPTb may be disposed to vertically (or in up-and-down direction) overlap the dam DM. For example, the second structure CPTb may be disposed under the first layer 310a of the dam DM. The second structure CPTb may include the first pattern 320a, the third pattern 330, and the second patterns 340 and 341. The second structure CPTb may be a structure in which the first pattern 320a, the third pattern 330, and the second patterns 340 and 341 are disposed. The first pattern 320a, the third pattern 330, and the second patterns 340 and 341 may be disposed on different layers, but embodiments of the present disclosure are not limited thereto.

The first pattern 320a may be disposed on the first insulating layer 115. The first pattern 320a may be covered with the second insulating layer 117. The third pattern 330 may be disposed on the second insulating layer 117. The third pattern 330 may be disposed so as not to overlap the first pattern 320a. For example, the third pattern 330 may be disposed so as not to vertically (or in up-and-down direction) overlap the first pattern 320a. For example, the third pattern 330 may be disposed to be staggered with the first pattern 320a on the second insulating layer 117.

The third pattern 330 may be disposed on the protective layer 119. The third pattern 330 may be covered with the protective layer 119. The protective layer 119 may include the first groove G1 formed by a step by the first pattern 320a disposed thereunder. The first groove G1 may be disposed at one or more sides of the third pattern 330. For example, the first groove G1 may be disposed between the first patterns 320a disposed below one or more sides of the third pattern 330.

The third insulating layer 121 may be disposed on the protective layer 119. The second patterns 340 and 341 may be disposed on the third insulating layer 121. The third insulating layer 121 may include the first groove G1 and a second groove G2. For example, the second groove G2 may overlap the first groove G1. The third insulating layer 121 may include the second groove G2 overlapping the first groove G1. For example, the third insulating layer 121 may include the second groove G2 vertically (or in up-and-down direction) overlapping the first groove G1. The second patterns 340 and 341 may be disposed to overlap the first pattern 320a and the third pattern 330. For example, the second patterns 340 and 341 may be disposed to vertically (or in up-and-down direction) overlap the first pattern 320a and the third pattern 330. Therefore, the second patterns 340 and 341 and the second insulating layer 121 may have an uneven shape (or a concave-convex shape), but embodiments of the present disclosure are not limited thereto. For example, the second patterns 340 and 341 and the second insulating layer 121 may have an uneven shape (or a concave-convex shape) in a cross-sectional view, but embodiments of the present disclosure are not limited thereto. For example, the uneven shape (or the concave-convex shape) may have the shape of the letter “V,” but embodiments of the present disclosure are not limited thereto.

According to one or more embodiments of the present disclosure, the first pattern 320a and the third pattern 330 may be disposed at staggered positions on different layers so that the first groove G1 and the second groove G2 overlap each other. For example, the first pattern 320a and the third pattern 330 may be disposed at the staggered positions on different layers so that the first groove G1 and the second groove G2 vertically (or in up-and-down direction) overlap each other.

The first groove G1 and the second groove G2 may prevent the propagation of the crack CR toward the display area AA or delay the propagation time of the crack CR. For example, when the crack CR propagates in a horizontal direction of the fourth insulating layer 123, as marked by the arrow in FIG. 8, the propagation time of the crack may be blocked by the second patterns 340 and 341 including the material filing the second groove G2. For example, the material filling the second groove G2 may be a metal material, but embodiments of the present disclosure are not limited thereto. Further, the propagation time of the crack CR may be delayed by the uneven shapes (or a concave-convex shape) formed by the first groove G1 and the second groove G2.

Referring to FIG. 9, a third structure CPTc may be disposed to overlap the dam DM. For example, the third structure CPTc may be disposed to vertically (or in up-and-down direction) overlap the dam DM. For example, the third structure CPTc may be disposed under the first layer 310a of the dam DM. The third structure CPTc may include one or more third patterns 330a, 330b, and 330c, and the second patterns 340 and 341. The one or more third patterns 330a, 330b, and 330c, and the second patterns 340 and 341 may be disposed on different layers, but embodiments of the present disclosure are not limited thereto. The third structure CPTc may be a structure in which the one or more third patterns 330a, 330b, and 330c and the second patterns 340 and 341 are disposed or stacked, but embodiments of the present disclosure are not limited thereto. Each of the patterns 330a, 330b, 330c, 340, 341 can be also referred to as a corresponding “metal layer pattern.”

The one or more third patterns 330a, 330b, and 330c may be disposed on the second insulating layer 117. The one or more third patterns 330a, 330b, and 330c may include the 3-1 sub-metal pattern 330a, the 3-2 sub-metal pattern 330b, and the 3-3 sub-metal pattern 330c. The one or more third sub-metal patterns 330a, 330b, and 330c may be made of the same material in the same process as the metal pattern TM, but embodiments of the present disclosure are not limited thereto.

The 3-1 sub-metal pattern 330a, the 3-2 sub-metal pattern 330b, and the 3-3 sub-metal pattern 330c may be disposed to be spaced apart from each other. Therefore, a space (or a separation space) may be present between the 3-1 sub-metal pattern 330a and the 3-2 sub-metal pattern 330b, and between the 3-2 sub-metal pattern 330b and the 3-3 sub-metal pattern 330c. The 3-1 to 3-3 sub-metal patterns 330a, 330b, and 330c may be covered with the protective layer 119.

The protective layer 119 may include the first groove G1. The first groove G1 may be configured in the space (the separation space) disposed between the 3-1 to 3-3 sub-metal patterns 330a, 330b, and 330c. The first groove G1 may be disposed at both sides of the 3-2 sub-metal pattern 330b. The third insulating layer 121 may be disposed on the protective layer 119.

The second patterns 340 and 341 may be disposed on the third insulating layer 121. The second patterns 340 and 341 may be formed of the same material in the same process as the second gate electrode GE2, but embodiments of the present disclosure are not limited thereto. The third insulating layer 121 may include the second groove G2 overlapping the first groove G1. For example, the third insulating layer 121 may include the second groove G2 vertically (or up-and-down direction) overlapping the first groove G1.

The second patterns 340 and 341 may fill the second groove G2. Therefore, the second patterns 340 and 341 and the third insulating layer 121 may have an uneven shape (or concave-convex shape) of the letter “W,” but embodiments of the present disclosure are not limited thereto. For example, the second patterns 340 and 341 and the third insulating layer 121 may have the uneven shape in the letter “W,” but embodiments of the present disclosure are not limited thereto. The second patterns 340 and 341 may overlap the one or more third patterns 330a, 330b, and 330C. For example, the second patterns 340 and 341 may vertically (or in up-and-down direction) overlap the one or more third patterns 330a, 330b, and 330C.

According to one or more embodiments of the present disclosure, the third structure CPTc disposed to overlap the dam DM can prevent the propagation of the crack CR by the first groove G1 and the second groove G2 as marked by the arrow. Further, the propagation time of the crack CR may be delayed by the uneven shapes (or concave-convex shapes) formed by the first groove G1 and the second groove G2.

Referring to FIG. 10, the fourth structure CPTd may include the one or more first patterns 320a and 320b and the second patterns 340 and 341. The fourth structure CPTd may include the one or more first patterns 320a and 320b and the second patterns 340 and 341. The plurality of fourth structures CPTd may be structures in which the one or more first patterns 320a and 320b and the second patterns 340 and 341 are stacked or disposed, but embodiments of the present disclosure are not limited thereto. The one or more first patterns 320a and 320b and the one or more second patterns 340 and 341 may be disposed on different layers, but embodiments of the present disclosure are not limited thereto.

The one or more first patterns 320a and 320b may include the first pattern 320a and the second pattern 320b. The first pattern 320a and the second pattern 320b may be disposed to be spaced apart from each other on the first insulating layer 115. Therefore, a space may be present between the first pattern 320a and the second pattern 320b. The first and second patterns 320a and 320b may be covered with the second insulating layer 117. The second insulating layer 117 may be disposed on the first and second patterns 320a and 320b.

The second insulating layer 117 may be covered with the protective layer 119. The protective layer 119 may be disposed on the second insulating layer 117. The protective layer 119 may include the first groove G1 formed by the space between the first patterns 320a and 320b. The third insulating layer 121 may be disposed on the protective layer 119 including the first groove G1. The third insulating layer 121 may include the second groove G2 overlapping the first groove G1. For example, the third insulating layer 121 may include the second groove G2 vertically (or up-and-down direction) overlapping the first groove G1.

The second patterns 340 and 341 may be disposed on the third insulating layer 121. The second patterns 340 and 341 may fill the second groove G2. The second patterns 340 and 341 may be disposed to overlap the one or more first patterns 320a and 320b. For example, the second patterns 340 and 341 may be disposed to vertically (or in up-and-down direction) overlap the one or more first patterns 320a and 320b. Therefore, the second patterns 340 and 341 and the third insulating layer 121, the protective layer 119, and the second insulating layer 117 that are disposed under the second patterns 340 and 341 may have an uneven shape (or a concave-convex shape), but embodiments of the present disclosure are not limited thereto. For example, the second patterns 340 and 341 and the third insulating layer 121, the protective layer 119, and the second insulating layer 117 that are disposed under the second patterns 340 and 341 may have the uneven shape (or the concave-convex shape) in a cross-sectional view, but embodiments of the present disclosure are not limited thereto. For example, the uneven shape (or the concave-convex shape) may have the shape of the letter “V,” but embodiments of the present disclosure are not limited thereto.

According to one or more embodiments of the present disclosure, the fourth structure CPTd disposed to overlap the dam DM may block or at least reduce the propagation of the crack CR toward the display area AA by the first groove G1 and the second groove G2. Further, as the length of the crack propagation path is increased by the uneven shape (or the concave-convex shape) formed by the first groove G1 and the second groove G2, the propagation time of the crack CR may be delayed.

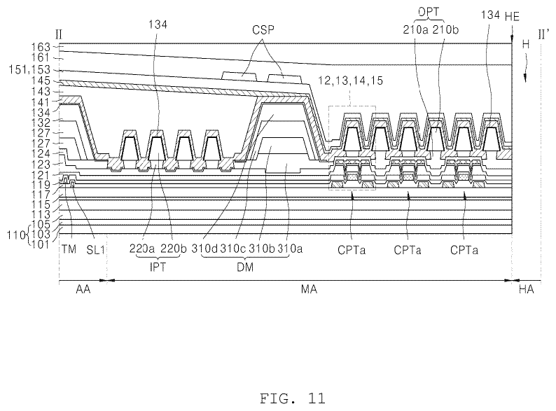

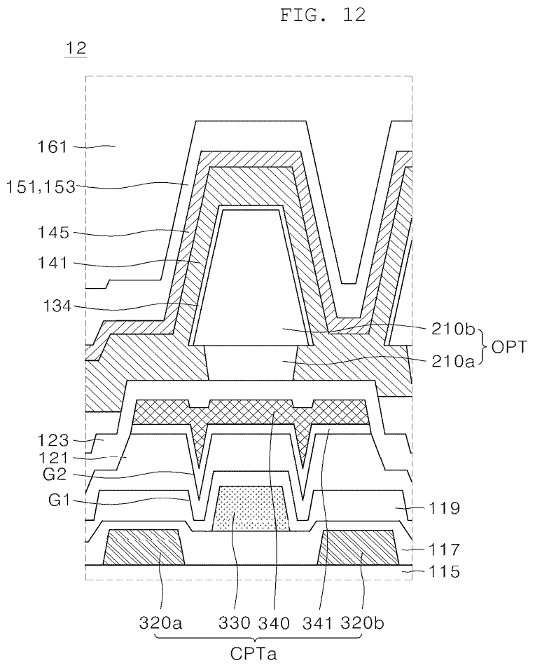

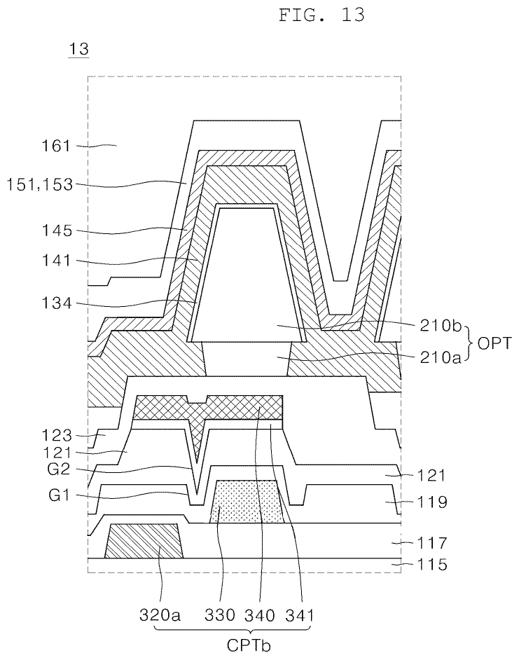

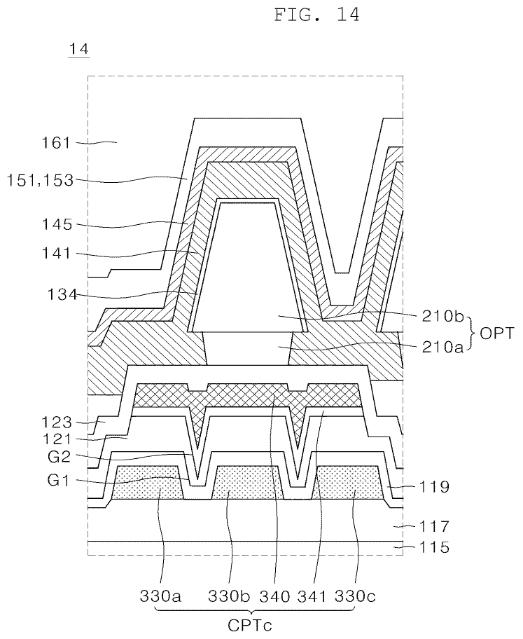

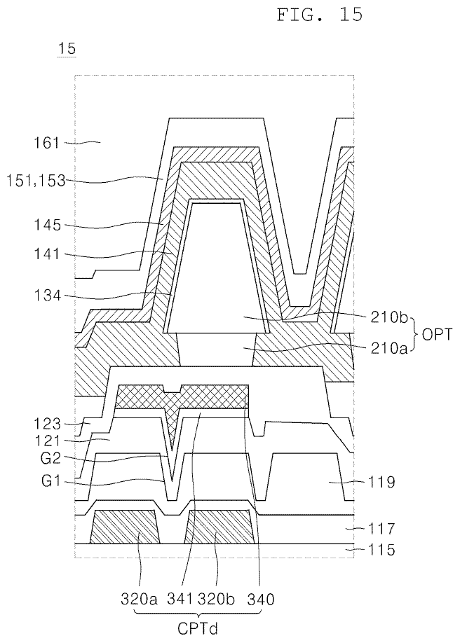

FIG. 11 illustrates a cross-sectional view of line II-II′ in FIG. 4 according to one or more embodiments of the present disclosure. FIG. 12 illustrates an enlarged cross-sectional view of area 12 in FIG. 11 according to one or more embodiments of the present disclosure. FIG. 13 illustrates another modified example of a structure in area 13 in FIG. 11 according to one or more embodiments of the present disclosure. FIG. 14 is another modified example of a structure in area 14 in FIG. 11 according to one or more embodiments of the present disclosure. FIG. 15 illustrates another modified example of a structure in area 15 in FIG. 11 according to one or more embodiments of the present disclosure. Since FIGS. 11 to 15 are substantially the same as FIG. 10, the same reference numerals are denoted, and duplicate descriptions thereof are omitted or briefly described.

Referring to FIGS. 11 and 12, a plurality of first structures CPTa may be disposed at the first area of the second area MA in which the plurality of first barrier patterns OPT are disposed. For example, one first structure CPTa may be disposed to overlap at least one first barrier pattern OPT. For example, the one first structure CPTa may be disposed to vertically (or in up-and-down direction) overlap at least one first barrier pattern OPT. The first structure CPTa may be disposed under an even-numbered first barrier pattern OPT among the plurality of first barrier patterns OPT, but is not limited thereto. In another example, the first structure CPTa may be disposed under an odd-numbered first barrier pattern OPT. In one or more embodiments, the first structure CPTa overlaps one of an odd-numbered first barrier pattern OPT without overlapping an even-numbered first barrier pattern OPT. In one or more other embodiments, the first structure CPTa overlaps the even-numbered first barrier pattern OPT without overlapping the odd-numbered first barrier pattern OPT.

The first structure CPTa may be disposed under the lower structure 210a of the first barrier pattern OPT. The first structure CPTa may include the one or more first patterns 320a and 320b, the third pattern 330, and the second patterns 340 and 341. The one or more first patterns 320a and 320b, the third pattern 330, and the second patterns 340 and 341 may be disposed on different layers, but embodiments of the present disclosure are not limited thereto.

Each of the one or more first patterns 320a and 320b, the third pattern 330, and the second patterns 340 and 341 disposed on different layers may be insulated (or isolated) therebetween in the second insulating layer 117, the protective layer 119, or the third insulating layer 121.

The protective layer 119 may include the first groove G1. The first groove G1 may be formed by a step by a space (or a separation space) between the first and second patterns 320a and 320b. The first groove G1 may be disposed at both sides of the third pattern 330. The third insulating layer 121 may include the second groove G2 overlapping the first groove G1. For example, the third insulating layer 121 may include the second groove G2 vertically (or up-and-down direction) overlapping the first groove G1. The second patterns 340 and 341 may fill the second groove G2. The second patterns 340 and 341, the third insulating layer 121, and the protective layer 119 may have an uneven shape (or a concave-convex shape), but embodiments of the present disclosure are not limited thereto. The second patterns 340 and 341, the third insulating layer 121, and the protective layer 119 may have the uneven shape (or the concave-convex shape) in a cross-sectional view, but embodiments of the present disclosure are not limited thereto. For example, the uneven shape (or the concave-convex shape) may have the shape of the letter “W,” but embodiments of the present disclosure are not limited thereto. The second patterns 340 and 341 may overlap the first patterns 320a and 320b and the third pattern 330. For example, the second patterns 340 and 341 may vertically (or in up-and-down direction) overlap the first and second patterns 320a and 320b and the third pattern 330. The first and second patterns 320a and 320b and the third pattern 330 may be disposed to have a staggered structure that does not overlap each other. For example, the third pattern 330 may be disposed at a position corresponding to the space (the separation space) between the first and second patterns 320a and 320b. The second patterns 340 and 341 may be covered with the fourth insulating layer 123. The fourth insulating layer 123 may be disposed on the second patterns 340 and 341. The lower structure 210a of the first barrier pattern OPT may be disposed on the fourth insulating layer 123.

The first groove G1 and the second groove G2 of the first structure CPTa may prevent the crack from propagating toward the display area AA or delay the propagation time of the crack by increasing the length of the crack propagation path. Therefore, it is possible to prevent the occurrence of dark spot defects or line defects caused by the crack, thereby improving the reliability of the display apparatus.

Referring to FIG. 13, the second structure CPTb may be disposed to overlap the first barrier pattern OPT. For example, the second structure CPTb may be disposed to vertically (or in up-and-down direction) overlap the first barrier pattern OPT. For example, the second structure CPTb may be disposed under the lower structure 210a of the first barrier pattern OPT. The second structure CPTb may include the first pattern 320a, the third pattern 330, and the second patterns 340 and 341. The first pattern 320a, the third pattern 330, and the second patterns 340 and 341 may be disposed on different layers, but embodiments of the present disclosure are not limited thereto.

The first pattern 320a may be disposed on the first insulating layer 115. An exposed surface of the first pattern 320a may be covered with the second insulating layer 117. The third pattern 330 may be disposed on the second insulating layer 117. The third pattern 330 may be disposed so as not to overlap the first pattern 320a. For example, the third pattern 330 may be disposed so as not to vertically (or up-and-down direction) overlap the first pattern 320a. The third pattern 330 may be disposed to have a staggered structure with the first pattern 320a.

The third pattern 330 may be disposed on the protective layer 119. The third pattern 330 may be covered with the protective layer 119. The protective layer 119 may include the first groove G1. The first groove G1 may be disposed at one or more sides of the third pattern 330. For example, the first groove G1 may be disposed between the first patterns 320a disposed below one or more sides of the third pattern 330.

The third insulating layer 121 may be disposed on the protective layer 119. The second patterns 340 and 341 may be disposed on the third insulating layer 121. The third insulating layer 121 may include the second groove G2 overlapping the first groove G1. For example, the third insulating layer 121 may include the second groove G2 vertically (or in up-and-down direction) overlapping the first groove G1. The second patterns 340 and 341 may be disposed to overlap the first pattern 320a and the third pattern 330. For example, the second patterns 340 and 341 may be disposed to vertically (or in up-and-down direction) overlap the first pattern 320a and the third pattern 330. Therefore, the second patterns 340 and 341 and the third insulating layer 121 may have an uneven shape (or a concave-convex shape), but embodiments of the present disclosure are not limited thereto. For example, the second patterns 340 and 341 and the third insulating layer 121 may have an uneven shape (or a concave-convex shape) in a cross-sectional view, but embodiments of the present disclosure are not limited thereto. For example, the uneven shape (or the concave-convex shape) may have the shape of the letter “V,” but embodiments of the present disclosure are not limited thereto.

Referring to FIG. 14, the third structure CPTc may be disposed to overlap the first barrier pattern OPT. The third structure CPTc may be disposed to vertically (or in up-and-down direction) overlap the first barrier pattern OPT. For example, the third structure CPTc may be disposed under the lower structure 210a of the first barrier pattern OPT. The third structure CPTc may include the one or more third patterns 330a, 330b, and 330c and the second patterns 340 and 341. The one or more third patterns 330a, 330b, and 330c and the second patterns 340 and 341 may be disposed on different layers, but embodiments of the present disclosure are not limited thereto.

The one or more third patterns 330a, 330b, and 330c may include the 3-1 sub-metal pattern 330a, the 3-2 sub-metal pattern 330b, and the 3-3 sub-metal pattern 330c. The 3-1 sub-metal pattern 330a, the 3-2 sub-metal pattern 330b, and the 3-3 sub-metal pattern 330c may be disposed on the second insulating layer 117. For example, each of the 3-1 sub-metal pattern 330a, the 3-2 sub-metal pattern 330b, and the 3-3 sub-metal pattern 330c may be disposed on the second insulating layer 117 with the space (or the separation space) interposed therebetween. The protective layer 119 may be disposed on the 3-1 to 3-3 sub-metal patterns 330a, 330b, and 330c. The 3-1 to 3-3 sub-metal patterns 330a, 330b, and 330c may be covered with the protective layer 119.

The protective layer 119 may include the first groove G1. The first groove G1 may be disposed at both sides of the 3-2 sub-metal pattern 330b. The third insulating layer 121 may be disposed on the protective layer 119.

The second patterns 340 and 341 may be disposed on the third insulating layer 121. The third insulating layer 121 may include the second groove G2 overlapping the first groove G1. For example, the third insulating layer 121 may include the second groove G2 vertically (or up-and-down direction) overlapping the first groove G1.

The second patterns 340 and 341 may fill the second groove G2. Therefore, the second patterns 340 and 341 and the third insulating layer 121 may have an uneven shape (or a concave-convex shape) of the letter “W,” but embodiments of the present disclosure are not limited thereto. For example, the second patterns 340 and 341 and the third insulating layer 121 may have the uneven shape (or the concave-convex shape) in the letter “W,” but embodiments of the present disclosure are not limited thereto. The second patterns 340 and 341 may overlap the one or more third patterns 330a, 330b, and 330C. For example, the second patterns 340 and 341 may vertically (or up-and-down direction) overlap the one or more third patterns 330a, 330b, and 330C.

Referring to FIG. 15, the fourth structure CPTd may include the one or more first patterns 320a and 320b and the second patterns 340 and 341. The one or more first patterns 320a and 320b and the one or more second patterns 340 and 341 may be disposed on different layers, but embodiments of the present disclosure are not limited thereto.

The one or more first patterns 320a and the second pattern 320b may be disposed to be spaced apart from each other on the first insulating layer 115. Therefore, spaces may be present between the one or more first pattern 320a and the second pattern 320b. The first and second patterns 320a and 320b may be covered with the second insulating layer 117. The second insulating layer 117 may be disposed on the first and second patterns 320a and 320b.

The second insulating layer 117 may be covered with the protective layer 119. The protective layer 119 may be disposed on the second insulating layer 117. The protective layer 119 may include the first groove G1. The first groove G1 may be formed by the space between the first and second patterns 320a and 320b. The third insulating layer 121 may be disposed on the protective layer 119 including the first groove G1. The third insulating layer 121 may include the second groove G2 overlapping the first groove G1. For example, the third insulating layer 121 may include the second groove G2 vertically (or up-and-down direction) overlapping the first groove G1.

The second patterns 340 and 341 may be disposed on the third insulating layer 121. The second patterns 340 and 341 may fill the second groove G2. The second patterns 340 and 341 may be disposed to overlap the first and second patterns 320a and 320b. For example, the second patterns 340 and 341 may be disposed to vertically (or in up-and-down direction) overlap the first and second patterns 320a and 320b. Thus, the second patterns 340 and 341 and the third insulating layer 121, the protective layer 119, and the second insulating layer 117 that are disposed under the second patterns 340 and 341 may have an uneven shape (or a concave-convex shape), but embodiments of the present disclosure are not limited thereto. For example, the second patterns 340 and 341 and the third insulating layer 121, the protective layer 119, and the second insulating layer 117 that are disposed under the second patterns 340 and 341 may have the uneven shape (or the concave-convex shape) in a cross-sectional view, but embodiments of the present disclosure are not limited thereto. For example, the uneven shape (or the concave-convex shape) may have the shape of the letter “V,” but embodiments of the present disclosure are not limited thereto.

According to one or more embodiments of the present disclosure, each of the structures CPTa, CPTb, CPTc, and CPTd includes a configuration disposed under the dam DM or under the first barrier pattern OPT, but is limited thereto. For example, each of the structures CPTa, CPTb, CPTc, and CPTd may be disposed together under the dam DM and under the first barrier pattern OPT. In this case, it is possible to further improve the effect of blocking the path through which the crack may propagate. Further, as the crack propagation path increases, the crack propagation time may be further delayed.

A display apparatus according to various embodiments of the present disclosure may be described as follows.

A display apparatus according to various embodiments of the present disclosure may include a display area disposed on a substrate and including a plurality of light emitting elements and a plurality of transistors, a non-display area surrounding the display area, a first area in the display area and including a hole, and a second area between the first area and the display area and including a structure.

According to various embodiments of the present disclosure, the second area may include a dam disposed between the hole and the display area, a plurality of first barrier patterns between the hole and the dam, and a plurality of second barrier patterns between the dam and the display area.

According to various embodiments of the present disclosure, the structure may be disposed to overlap at least one of the dam and the plurality of first barrier patterns.

According to various embodiments of the present disclosure, the structure may be disposed to overlap one of an odd-numbered first barrier pattern and an even-numbered first barrier pattern among the plurality of first barrier patterns.

According to various embodiments of the present disclosure, the structure may include one or more first patterns disposed with a space interposed therebetween, a second pattern overlapping the one or more first patterns, a first insulating layer between the first pattern and the second pattern and including a first groove disposed to correspond to the space, and a second insulating layer including a second groove overlapping the first groove.

According to various embodiments of the present disclosure, the display apparatus may further include third patterns that do not overlap the first pattern and are disposed to correspond to spaces of the one or more first patterns. The third pattern may be disposed on a different layer from the first pattern and the second pattern.

According to various embodiments of the present disclosure, one of the first groove and the second groove may be disposed at one or more sides of the third pattern.

According to various embodiments of the present disclosure, one of the first groove and the second groove may include an uneven shape.

According to various embodiments of the present disclosure, the structure may include one or more third patterns disposed with a space interposed therebetween, a second pattern overlapping the one or more third patterns, a first insulating layer disposed between the third pattern and the second pattern and including a first groove disposed to correspond to the space, and a second insulating layer including a second groove overlapping the first groove.

According to various embodiments of the present disclosure, the one or more third patterns may include a 3-1 sub-metal pattern, a 3-2 sub-metal pattern, and a 3-3 sub-metal pattern. One of the first groove and the second groove may be disposed at both sides of the 3-2 sub-metal pattern.

According to various embodiments of the present disclosure, each of the plurality of light emitting elements may include a first electrode, a second electrode, and a light emitting layer between the first electrode and the second electrode.

According to various embodiments of the present disclosure, each of the first barrier pattern and the second barrier pattern may include a lower structure and an upper structure on the lower structure. A portion of the light emitting layer may be disposed along an upper surface of the upper structure without being along side walls of the lower structure. The upper structure may be wider than the lower structure.

According to various embodiments of the present disclosure, the portion of the light emitting layer may be disconnected from the light emitting layer included in the plurality of light emitting elements at an end of the upper structure of one of the first barrier pattern and the second barrier pattern.

According to various embodiments of the present disclosure, the first barrier pattern may be spaced apart from the hole and surround the hole in a plan view of the display apparatus. The second barrier pattern may be spaced apart from the dam and surround the dam in the plan view.

According to various embodiments of the present disclosure, the first barrier pattern, the second barrier pattern, the dam, and the structure may include a closed curve shape.

According to various embodiments of the present disclosure, a width of the structure may be smaller than a width of the dam.

According to various embodiments of the present disclosure, the plurality of transistors may be configured in one of an oxide semiconductor layer and a low-temperature polysilicon semiconductor layer or a combination thereof.

The display apparatus according to various embodiments of the present disclosure may further include an encapsulation part on the light emitting element and a touch part on the encapsulation part. The touch part may be configured to sense touch.

According to various embodiments of the present disclosure, at least one or more of a camera, a proximity sensor, a gesture sensor, a color sensor, a biometric sensor, and an infrared sensor may be disposed in the hole.

A display apparatus according to various embodiments of the present disclosure may be applied to a mobile apparatus, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display apparatus, a theater display apparatus, a television, a wallpaper apparatus, a signage apparatus, a game apparatus, a laptop computer, a monitor, a camera, a camcorder, a home appliances, etc.

It will be apparent to those skilled in the art that various modifications and variations may be made in the present disclosure without departing from the scope of the disclosures. Thus, it is intended that the present disclosure covers the modifications and variations of this disclosure that come within the scope of the appended claims and their equivalents.

What is claimed is:

1. A display apparatus, comprising:
a display area on a substrate, the display area including a plurality of light emitting elements and a plurality of transistors;
a non-display area surrounding the display area;
a first area of the display area, the first area including a hole; and
a second area of the display area that is between the first area and a remainder of the display area that is outside the first area and the second area, the second area including a structure having a plurality of metal patterns on different layers with at least one insulating layer between the plurality of metal patterns,
wherein the structure reduces at least one of permeation of external moisture to the display area and propagation of one or more cracks in the at least one insulating layer through the first area.

2. The display apparatus of claim 1, wherein the second area includes:
a dam between the hole and the plurality of light emitting elements;
a plurality of first barrier patterns between the hole and the dam; and
a plurality of second barrier patterns between the dam and the plurality of light emitting elements display area.

3. The display apparatus of claim 2, wherein the structure overlaps at least one of the dam and the plurality of first barrier patterns.

4. The display apparatus of claim 2, wherein the structure overlaps one of an odd-numbered first barrier pattern of the plurality of first barrier patterns without overlapping an even-numbered first barrier pattern of the plurality of first barrier patterns or overlaps the even-numbered first barrier pattern without overlapping the odd-numbered first barrier pattern.

5. The display apparatus of claim 1, wherein the plurality of metal patterns include:
one or more first metal patterns with a space interposed between the one or more first metal patterns; and
a second metal pattern overlapping the one or more first pattern patterns,
wherein the at least one insulating layer comprises:
a first insulating layer between the one or more first metal patterns and the second metal pattern, the first insulating layer including a first groove that corresponds to the space; and
a second insulating layer including a second groove overlapping the first groove.

6. The display apparatus of claim 5, wherein the plurality of metal patterns further comprise a plurality of third metal patterns that are non-overlapping with the one or more first metal patterns, the plurality of third metal patterns correspond to a plurality of spaces of the one or more first metal patterns,
wherein a third metal pattern of the plurality of third metal patterns is on a different layer from the one or more first metal patterns and the second metal pattern.

7. The display apparatus of claim 6, wherein one of the first groove and the second groove is at one or more sides of the third metal pattern.

8. The display apparatus of claim 5, wherein one of the first groove and the second groove includes a concave-convex shape in a cross-sectional view of one of the first groove and the second groove.

9. The display apparatus of claim 1, wherein the plurality of metal patterns include:
one or more third metal patterns with a space interposed between the one or more third metal patterns; and
a second metal pattern overlapping the one or more third metal patterns;
wherein the at least one insulating layer comprises:
a first insulating layer between the one or more third metal patterns and the second pattern, the first insulating layer including a first groove that corresponds to the space; and
a second insulating layer including a second groove overlapping the first groove.

10. The display apparatus of claim 9, wherein the one or more third patterns include a first sub-metal pattern, a second sub-metal pattern, and a third sub-metal pattern, and
wherein one of the first groove and the second groove is at both sides of the second sub-metal pattern.

11. The display apparatus of claim 1, wherein each of the plurality of light emitting elements includes a first electrode, a second electrode, and a light emitting layer between the first electrode and the second electrode.

12. The display apparatus of claim 11, wherein each of a first barrier pattern of the plurality of first barrier patterns and a second barrier pattern of the plurality of second barrier patterns includes a lower structure and an upper structure on the lower structure that is wider than the lower structure, and
wherein a portion of the light emitting layer is along an upper surface of the upper structure without being along side walls of the lower structure.

13. The display apparatus of claim 12, wherein the portion of the light emitting layer is disconnected from the light emitting layer included in the plurality of light emitting elements at an end of the upper structure of one of the first barrier pattern and the second barrier pattern.

14. The display apparatus of claim 2, wherein a first barrier pattern of the plurality of first barrier patterns is spaced apart from the hole and surrounds the hole in a plan view of the display apparatus, and a second barrier pattern of the plurality of second barrier patterns is spaced apart from the dam and surrounds the dam in the plan view.

15. The display apparatus of claim 2, wherein a first barrier pattern of the plurality of first barrier patterns, a second barrier pattern of the plurality of second barrier patterns, the dam, and the structure include a closed curve shape.

16. The display apparatus of claim 2, wherein a width of the structure is smaller than a width of the dam.

17. The display apparatus of claim 1, wherein the plurality of transistors include at least one of an oxide semiconductor layer, a low-temperature polysilicon semiconductor layer, or combinations thereof.

18. The display apparatus of claim 1, further comprising:
an encapsulation part on the plurality of light emitting elements; and
a touch part on the encapsulation part, the touch part configured to sense touch.

19. The display apparatus of claim 1, wherein at least one or more of a camera, a proximity sensor, a gesture sensor, a color sensor, a biometric sensor, and an infrared sensor is in the hole.

20. A display apparatus, comprising:
a substrate having a first area including a hole through the substrate, a second area surrounding the first area, and a third area surrounding the first area and the second area;
a plurality of insulating layers extending from the second area to the third area;
a plurality of transistors on the plurality of insulating layers in the third area;
a plurality of light emitting elements in the third area, the plurality of light emitting elements connected to the plurality of transistors and configured to emit light; and
a structure in the second area that includes a plurality of metal patterns that are on different layers from each other such that an insulating layer from the plurality of insulating layers is between the plurality of metal patterns,
wherein the plurality of metal patterns are in the second area without being in the third area.

21. The display apparatus of claim 20, further comprising:
a plurality of grooves in at least one insulating layer of the plurality of insulating layers, each of the plurality of grooves extending from an upper surface of the at least one insulating layer towards a lower surface of the at least one insulating layer.

22. The display apparatus of claim 21, wherein at least one metal pattern of the plurality of metal pattern is within a groove of the plurality of grooves.

23. The display apparatus of claim 21, wherein a first groove of the plurality of grooves overlaps a second groove of the plurality of grooves.

24. The display apparatus of claim 20, wherein the plurality of metal patterns reduce permeation of external moisture to the display area through the plurality of insulating layers or reduce propagation of a crack in the at least one insulating layer toward the display area.

25. The display apparatus of claim 20, wherein the plurality of metal patterns comprise:
a first metal pattern;
a second metal pattern on a same first insulating layer of the plurality of insulating layers as the first metal pattern and spaced apart from the first metal pattern;
a third metal pattern on a second insulating layer of the plurality of insulating layers, the second insulating layer between the third metal pattern and the first metal pattern and the second metal pattern;
a fourth metal pattern on a third insulating layer of the plurality of insulating layers, the third insulating layer between the fourth metal pattern and the third metal pattern; and
a fifth metal pattern on the fourth metal pattern without any of the plurality of insulating layers between the fifth metal pattern and the fourth metal pattern,
wherein the fourth metal pattern and the fifth metal pattern overlap the first metal pattern, the second metal pattern and the third metal pattern, and the third metal pattern is non-overlapping with the first metal pattern and the second metal pattern.

26. The display apparatus of claim 20, wherein the plurality of metal patterns comprise:
a first metal pattern on a first insulating layer of the plurality of insulating layers;
a second metal pattern on a second insulating layer of the plurality of insulating layers;
a third metal pattern on a third insulating layer of the plurality of insulating layers; and
a fourth metal on the third metal pattern without any of the plurality of insulating layers between the fourth metal pattern and the third metal pattern, wherein the third metal pattern and the fourth metal pattern overlap the first metal pattern and the second metal pattern, and the first metal pattern is non-overlapping with the second metal pattern.

27. The display apparatus of claim 20, wherein the plurality of metal patterns comprise:
a set of metal patterns on a first insulating layer of the plurality of insulating layers, the set of metal patterns spaced apart from each other;
a first metal pattern on a second insulating layer of the plurality of insulating layers; and
a second metal pattern on the first metal pattern without any of the plurality of insulating layers between the second metal pattern and the first metal pattern,
wherein the first metal pattern and the second metal pattern overlaps at least a portion of each metal pattern of the set of metal patterns.

28. The display apparatus of claim 20, further comprising:
a dam in the second area, the dam overlapping the structure.

29. The display apparatus of claim 20, further comprising:
a dam in the second area; and
a plurality of barrier patterns in the second area, the plurality of barrier patterns between the dam and the hole,
wherein a barrier pattern of the plurality of berries patterns overlaps the structure.
